(19) United States
(12) Patent Application Publication
(10) Pub. No.: US 2017/0374740 A1
(43) Pub. Date: Dec. 28, 2017

(54) DISPLAY DEVICE

(71) Applicant: Sharp Kabushiki Kaisha, Sakai City, Osaka (JP)

(72) Inventor: KATSUHIRO YAMAGUCHI, Sakai City (JP)

(21) Appl. No.: 15/539,501

(22) PCT Filed: Dec. 18, 2015
(86) PCT No.: PCT/JP2015/085480

§ 371 Date: Jun. 23, 2017

(30) Foreign Application Priority Data
Dec. 25, 2014 (JP) 2014-262142

(51) Int. Cl. H05K 1/14; G02F 1/1345; G02F 1/133; H05K 1/02

(52) U.S. Cl. CPC H05K 1/144; H05K 1/028; G02F 1/13452; G02F 1/13306; G09G 2380/02; H05K 2201/041; H05K 2201/10136

(57) ABSTRACT

A liquid crystal display device 10 includes a liquid crystal panel 11 having a display area AA capable of displaying an image and a non-display area NAA outside the display area AA, a flexible board portion 40 having flexibility and connected to the non-display area NAA at a first end 40a thereof, and a rigid board portion 30 connected to a second end 40b of the flexible board portion 40 opposite the first end 40a and configured to supply signals to the liquid crystal panel 11 through the flexible board portion 40. The rigid board portion 30 at least includes a rigid portion 31a having a higher rigidity than the flexible board portion 40, a rigid portion 31b located next to the rigid portion 31a and having a higher rigidity than the flexible board portion 40, and a low rigidity portion 32a located between the rigid portion 31a and the rigid portion 31b and having a lower rigidity than the rigid portion 31a and the rigid portion 31b.

### TECHNICAL FIELD

The present invention relates to a display device.

### BACKGROUND ART

A mobile electrical device such as a mobile phone, a smart phone, and a tablet computer includes a display device having a display panel such as a liquid crystal panel. This type of display device includes a display panel having a display area displaying an image, a signal supply board connected to a signal supply source, and a flexible board connected to both the display panel and the signal supply board such that signals are sent to the display panel therethrough. One example of the display device of this type includes a known display device described in Patent Document 1 listed below.

In the display device described in Patent Document 1, a flexible printed board is used to connect a flexible liquid crystal display panel to a drive circuit board. Wiring patterns on the flexible printed board are connected to external connection electrode terminals of the liquid crystal display panel, and the flexible printed board is disconnected or cut in a connection direction at predetermined intervals to prevent thermal distortion at the connection portion caused by a difference between the thermal expansion of the liquid crystal display panel and that of the flexible printed board.

### RELATED ART DOCUMENT

### Patent Document

Patent Document 1: Japanese Unexamined Patent Application Publication No. H6-18914

### Problem to be Solved by the Invention

A decrease in the thickness of a display device and a decrease in the width of the frame of the display device have been increasingly demanded. To meet the demand, a rigid signal supply board configured to supply signals to the display panel through a flexible board is located closer to the display panel having a smaller thickness. In such a display device having a smaller thickness and including a narrower frame, the signal supply board may be deformed by, for example, heat generated during thermocompression bonding of the flexible board to the display panel. In such a case, a force is applied to the display panel from the signal supply board through the flexible board, leading to deformation of the display panel.

### DISCLOSURE OF THE PRESENT INVENTION

The present invention was made in view of the above-described circumstance. It is an object of the present invention to provide a display device in which a display panel is less likely to be deformed.

### Means for Solving the Problem

A display device according to the present invention includes a display panel having a display area capable of displaying an image and a non-display area outside the display area, a flexible board having flexibility and connected to the non-display area at a first end thereof, and a signal supply board connected to a second end of the flexible board opposite from the first end and configured to supply signals to the display panel through the flexible board. The signal supply board at least includes a first rigid portion having a higher rigidity than the flexible board, a second rigid portion located next to the first rigid portion and having a higher rigidity than the flexible board, and a low rigidity portion located between the first rigid portion and the second rigid portion and having a lower rigidity than the first rigid portion and the second rigid portion.

According to the invention, the displacement between the first rigid portion and the second rigid portion is absorbed by the deformation of the low rigidity portion, reducing the deformation of the first rigid portion and the second rigid portion. This reduces the force applied from the signal supply board to the display panel through the flexible board, which is generated by the deformation of the first rigid portion and the second rigid portion, reducing the deformation of the display panel caused by the deformation of a rigid section of the signal supply board.

The following configurations are preferable as aspects of the display device of the present invention.

(1) The non-display area extends along an edge of the display panel and the first rigid portion and the second rigid portion of the signal supply board are located next to each other along the edge of the display panel. This configuration reduces the deformation of the signal supply board in a direction along the edge of the display panel and thus reliably reduces the deformation of the display panel.

(2) The flexible board at least includes a first flexible portion and a second flexible portion separately located next to each other along the edge of the display panel with having a space between the first flexible portion and the second flexible portion. The first rigid portion and the second rigid portion of the signal supply board are respectively connected to the first flexible portion and the second flexible portion. The low rigidity portion of the signal supply board faces the space. This configuration enables the signal supply board to be connected to the flexible board at the first rigid portion and the second rigid portion, where the deformation is less likely to occur, and reduces the influence of the deformation of the low rigidity portion on the display panel through the flexible board.

(3) The flexible board is connected to the non-display area by thermocompression bonding. The signal supply board is integrally formed with the flexible board by stacking a rigid base member on a flexible base member constituting the flexible board. The rigid base member has a higher rigidity than the flexible base member. The low rigidity portion is constituted of at least a portion of the flexible base member. This configuration enables a so-called rigid flexible board integrally including the flexible board and the signal supply board to reliably have the low rigidity portion without the need for a separate flexible base member, for example. The deformation of the signal supply board caused by the heat generated during the thermocompression bonding of the flexible board to the display panel is absorbed by the low rigidity portion.

(4) The signal supply board is a separate member from the flexible board and is connected to the flexible board by thermocompression bonding. The low rigidity portion is a separate member from a flexible base member constituting the flexible board and at least constituted of a signal supply board side flexible base member having flexibility. With this configuration, the deformation of the signal supply board caused by heat generated during the thermocompression bonding of the signal supply board to the flexible board is absorbed by the low rigidity portion of the signal supply board.

(5) The low rigidity portion extends from a first edge of the signal supply board adjacent to the display panel to a second edge thereof remote from the display panel. The low rigidity portion constituted of the flexible base member enables the first rigid portion and the second rigid portion to be connected to each other through the flexible base member. This enables the low rigidity portion to extend from the first edge of the signal supply board to the second edge thereof, which is difficult if the low rigidity portion is constituted of a slit or the like in the signal supply board, for example. Then, with this configuration, the displacement between the first rigid portion and the second rigid portion is uniformly absorbed by the low rigidity portion from the first edge of the signal supply board to the second edge thereof, which is preferable.

(6) The low rigidity portion includes a slit extending through the signal supply board in a thickness direction thereof. This configuration enables the low rigidity portion to be readily formed, which is preferable.

(7) The slit is a cutout at a first edge of the signal supply board adjacent to the display panel. This configuration enables the low rigidity portion to readily absorb the deformation at the first edge of the signal supply board, and thus the force applied from the signal supply board to the display panel through the flexible board is reliably reduced.

(8) The slit is a cutout at a second edge of the signal supply board remote from the display panel. This configuration eliminates the need of positioning the slit away from the connection portion between the signal supply board and the flexible board and the need of routing wiring lines so as to avoid the slit, making it easy to design the signal supply board.

(9) The slit includes a plurality of slits located close to each other and in parallel to each other. With this configuration, the displacement in the signal supply board in an arrangement direction in which the slits are arranged is reliably absorbed. In addition, compared with a configuration in which one cutout extends over the area including the plurality of slits, the signal supply board readily has a larger surface area in an extending direction of the slits, readily enhancing the rigidity thereof.

(10) The display panel is a liquid crystal panel having liquid crystals sealed between two substrates. Such a display device has various uses as the liquid crystal display device and is applicable to various electronic devices such as a mobile phone, a smart phone, and a tablet computer, for example.

### Advantageous Effect of the Invention

The present invention provides a display device in which a display panel is less likely to be deformed.

### BRIEF DESCRIPTION OF THE DRAWINGS

FIG. 1 is a plan view illustrating a liquid crystal panel and a rigid flexible board according to a first embodiment of the present invention.

FIG. 2 is a schematic cross-sectional view illustrating a cross-sectional configuration taken in a long side direction of a liquid crystal display device.

FIG. 3 is a schematic cross-sectional view illustrating a cross-sectional configuration of a liquid crystal panel.

FIG. 4 is a cross-sectional view taken along line IV-IV in FIG. 4.

FIG. 5 is an exploded perspective view illustrating a configuration of the rigid flexible board.

FIG. 6 is a horizontal cross-sectional view illustrating the rigid flexible board to be connected to the liquid crystal panel.

FIG. 7 is a vertical cross-sectional view illustrating a step of mounting the rigid flexible board on the liquid crystal panel.

FIG. 8 is a horizontal cross-sectional view illustrating the rigid flexible board connected to the liquid crystal panel.

FIG. 9 is a magnified horizontal cross-sectional view illustrating a low rigidity portion in FIG. 8 in a magnified state.

FIG. 10 is a horizontal cross-sectional view illustrating a rigid flexible board according to a second embodiment of the present invention.

FIG. 11 is a plan view illustrating a liquid crystal panel and a rigid flexible board according to a third embodiment of the present invention.

FIG. 12 is a plan view illustrating a liquid crystal panel and a rigid flexible board according to a fourth embodiment of the present invention.

FIG. 13 is a cross-sectional view taken along line XIII-XIII in FIG. 12.

FIG. 14 is a plan view illustrating a liquid crystal panel and a rigid flexible board according to a fifth embodiment of the present invention.

FIG. 15 is a cross-sectional view taken along line XV-XV in FIG. 14.

FIG. 16 is a plan view illustrating a liquid crystal panel and a rigid flexible board according to a sixth embodiment of the present invention.

FIG. 17 is a plan view illustrating a liquid crystal panel and a rigid flexible board according to a seventh embodiment of the present invention.

FIG. 18 is a plan view illustrating a liquid crystal panel and a rigid flexible board according to an eighth embodiment of the present invention.

FIG. 19 is a plan view illustrating a liquid crystal panel and a rigid flexible board according to a ninth embodiment of the present invention.

FIG. 20 is a plan view illustrating a liquid crystal panel and a rigid flexible board according to a tenth embodiment of the present invention.

FIG. 21 is a plan view illustrating a liquid crystal panel and a rigid flexible board according to an eleventh embodiment of the present invention.

### MODE FOR CARRYING OUT THE INVENTION

### First Embodiment

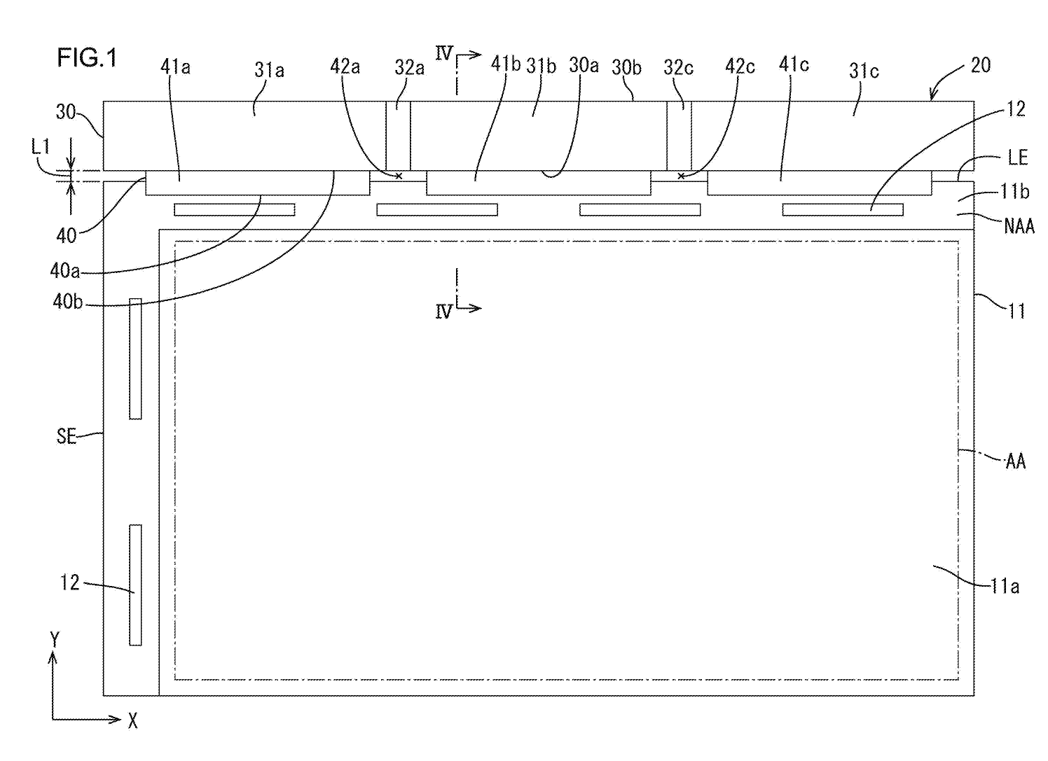

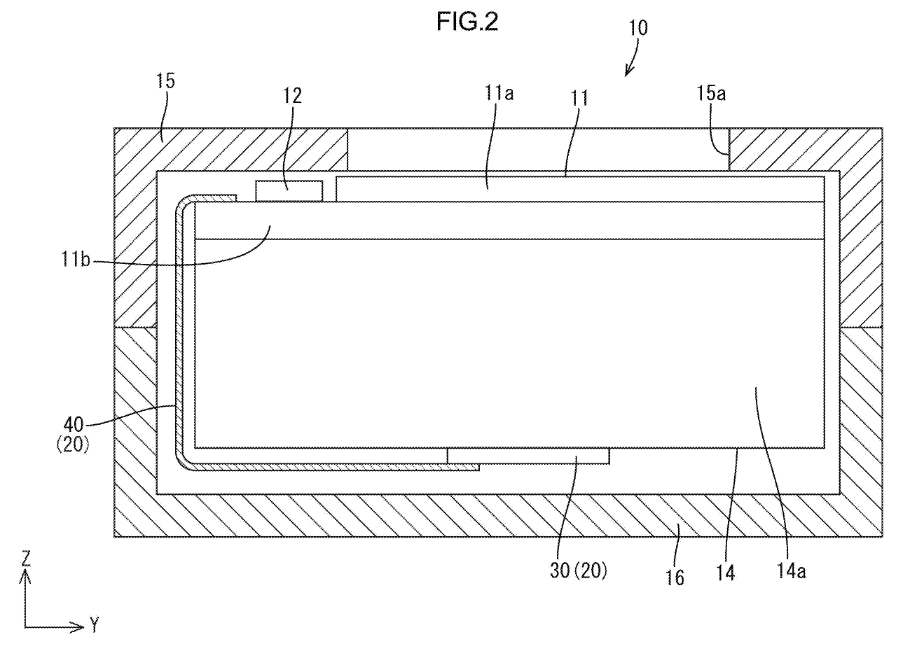

A first embodiment of the present invention is described with reference to FIG. 1 to FIG. 9. In this embodiment, a liquid crystal display device (display device) 10 is described as an example. The X axis, Y axis, and Z axis are indicated in some of the drawings, and each of the axes indicates the same direction in the respective drawings. The up and down direction is based on that of FIG. 2, and the upper side in FIG. 2 is a front side and the lower side in FIG. 2 is a rear side.

As illustrated in FIG. 1 and FIG. 2, the liquid crystal display device 10 includes a liquid crystal panel 11, drivers (mounted component) 21, which are mounted on the liquid crystal panel 11 and configured to drive the liquid crystal panel 11, a rigid flexible board 20 integrally including a rigid board portion (signal supply board, control circuit board) 30, which is configured to supply various input signals to the drivers 21, and a flexible board portion (flexible board, external connection component) 40, which electrically connects the liquid crystal panel 11 to a rigid board portion 30, and a backlight apparatus (lighting apparatus) 14, which is an external light source configured to provide light to the liquid crystal panel 11. The liquid crystal display device 10 further includes front and rear exterior members 15 and 16 housing and holding the liquid crystal panel 11 and the backlight apparatus 14, which are attached to each other. The front exterior member 15 has an opening 15a allowing an image displayed on the liquid crystal panel 11 to be seen from outside. The liquid crystal display device 10 according to this embodiment is used in various electronic devices (not illustrated) such as a mobile phone, a smart phone (including a phablet and the like), a tablet computer, a laptop computer, a mobile terminal device (including an electronic book, a PDA, and the like), a digital photo frame, a portable video game player, and an electronic ink paper. Thus, the liquid crystal panel 11 included in the liquid crystal display device 10 has a screen size of about a few inches to a dozen inches, which is categorized as a small size or a small to medium size in general.

The backlight apparatus 14 is briefly described first. As illustrated in FIG. 2, the backlight apparatus 14 includes a box-like shaped chassis 14a having an opening in the front (side adjacent to the liquid crystal panel 11), a light source (not illustrated) disposed in the chassis 14a (such as a cold-cathode tube, an LED, and an organic EL, for example), and an optical member (not illustrated) covering the opening of the chassis 14a. The optical member has a function of converting light from the light source into planar light, for example.

Next, the liquid crystal panel 11 is described. As illustrated in FIG. 1, the liquid crystal panel 11 has a horizontally elongated quadrilateral overall shape (rectangular shape) and includes a display area (active area) AA, which is capable of displaying an image, at a position closer to a first edge in the long side direction and a first edge in the short side direction (right lower side in FIG. 1) and a non-display area (non-active area) NAA, which does not display an image, at a position outside the display area AA. In other words, the non-display area NAA at least extends along a second edge LE extending in the long side direction of the liquid crystal panel 11 and a second edge SE extending in the short side direction. The non-display area NAA adjacent to the second edge LE extending in the long side direction of the liquid crystal panel 11 is a mounting area for the drivers 21 and the flexible board 13. The non-display area NAA adjacent to the edge LE extending in the long side direction has a width of about 2 mm to 3 mm, for example, to meet the demand for the liquid crystal panel 11 to have a smaller frame. In FIG. 1, a one-dot chain line extending in a frame-like shape slightly smaller than a CF substrate 11a indicates an outer shape of the display area AA, and an area outside the one-dot chain line is the non-display area NAA. In the drawings, the width of the non-display area NAA is larger than the actual width for ease of description. The long side direction of the liquid crystal panel 11 matches the X axis direction in the drawings and the short side direction matches the Y axis direction in the drawings.

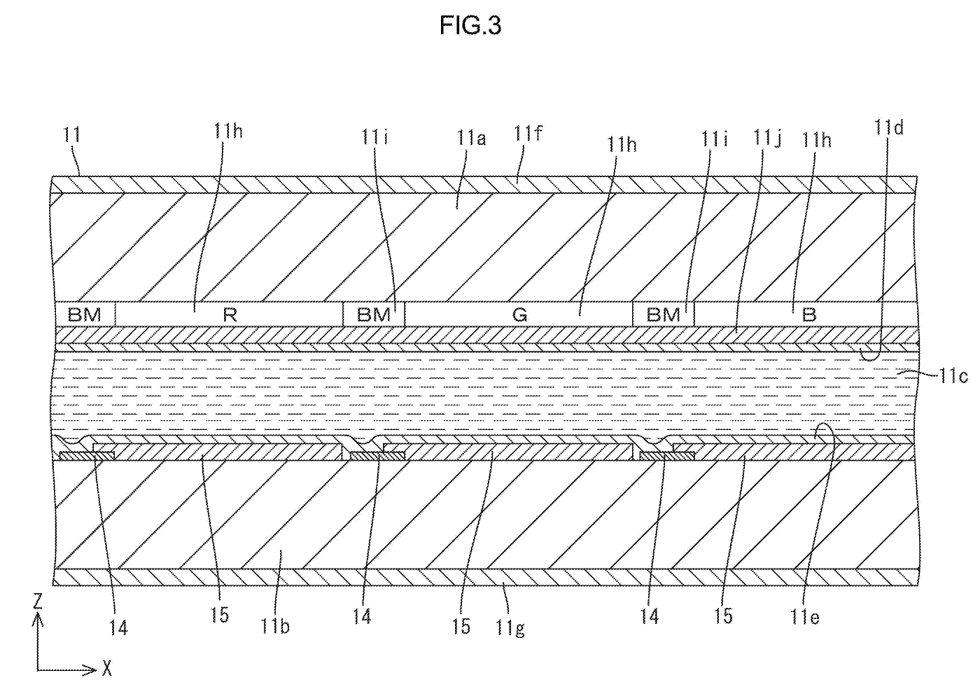

As illustrated in FIG. 3, the liquid crystal panel 11 includes two transparent (high light transmission) substrates 11a and 11b and a liquid crystal layer 11c sandwiched between the two substrates 11a and 11b. The liquid crystal layer 11c includes liquid crystal molecules, which are substances whose optical properties are changed by application of an electrical field. The substrates 11a and 11b are bonded together by a sealant, which is not illustrated, with a cell gap corresponding to the thickness of the liquid crystal layer 11c therebetween. The substrates 11a and 11b each include a glass substrate including an alkali-free glass or a quartz glass, for example, and a plurality of films laminated by a known photolithography method on the glass substrate. The substrate 11a on the front side (front surface side) is a CF substrate (counter substrate) 11a and the substrate 11b on the rear side (rear surface side) is an array substrate (a mounting substrate, a device substrate, an active matrix substrate) 11b. As illustrated in FIG. 2, the CF substrate 11a is slightly smaller than the array substrate 11b and bonded to the array substrate 11b with a first edge thereof extending in the long side direction and a first edge thereof extending in the short side direction (sides on the lower side and the right side in FIG. 2) being aligned with those of the array substrate 11b. Thus, the second edges LE and SE extending in the long side direction and the short side direction of the array substrate 11b do not overlap the CF substrate 11a over a predetermined area, and front and rear planar surface of the array substrate 11b are exposed to the outside. Alignment films 11d and 11e for orienting the liquid crystal molecules in the liquid crystal layer 11c are respectively formed on the inner surfaces of the substrates 11a and 11b. Furthermore, polarizing plates 11f and 11g are respectively attached to outer surfaces of the substrates 11a and 11b.

Subsequently, the configurations inside the display area AA of the array substrate 11b and the CF substrate 11a are briefly described. As illustrated in FIG. 3, many TFTs (Thin Film Transistor) 17, which are switching elements, and many pixel electrodes 18 are disposed next to each other in a matrix on the inner side of the array substrate 11b (side adjacent to the liquid crystal layer 11c, side facing the CF substrate 11a), and gate wiring lines and source wiring lines (both are not illustrated) are disposed in a grid shape so as to surround the TFTs 17 and the pixel electrodes 18. In other words, the TFTs 17 and the pixel electrodes 18 are placed next to each other in rows and columns at intersections of the gate wiring lines and the source wiring lines in a grid shape. The gate wiring lines and the source wiring lines are respectively connected to the gate electrodes and the source electrodes of the TFTs 17, and the pixel electrodes 18 are connected to drain electrodes of the TFTs 17. The pixel electrode 18 has a vertically elongated quadrilateral (rectangular) shape in plan view and is formed of a transparent electrode material such as ITO (Indium Tin Oxide) or ZnO (Zinc Oxide). Capacitor wiring lines (not illustrated) extending parallel to the gate wiring lines and intersecting the pixel electrodes 18 may be disposed on the array substrate 11b.

As illustrated in FIG. 3, color filters 11h each including a coloring portion of R (red), G (green), or B (blue), for example, arranged next to each other in a matrix is disposed on the CF substrate 11a so as to overlap the pixel electrodes 18 on the array substrate 11b in plan view. A light blocking layer (black matrix) 11i having a substantially grid shape is disposed between the respective coloring portions constituting the color filter 11h to prevent mixture of colors. The light blocking layer 11i overlaps the above-described gate wiring lines and the source wiring lines in plan view. A planar counter electrode 11j facing the pixel electrodes 18 on the array substrate 11b is disposed on surfaces of the color filters 11h and surfaces of the light blocking layers 11i. In the liquid crystal panel 11, three coloring portions of R (red), G (green), and B (blue) and three pixel electrodes 18 facing the respective coloring portions form one display pixel, which is a display unit. The display pixel includes a red pixel including R coloring portion, a green pixel including G coloring portion, and a blue pixel including B coloring portion. The pixels of each color are repeatedly arranged in the row direction (X axis direction) on a planar surface of the liquid crystal panel 11 to form a pixel group. Many pixel groups are arranged in the column direction (Y axis direction).

Due to a recent demand for the liquid crystal panel 11 to have a smaller thickness and a smaller weight, the glass substrates of the CF substrate 11a and the array substrate 11b included in the liquid crystal panel 11 are also demanded to have a smaller thickness. To meet the demand, in the present embodiment, various films are formed on the glass substrate of each of the CF substrate 11a and the array substrate 11b, and after patterning, etching (wet etching) is performed to a planar surface of the glass substrate opposite the planar surface having the various films thereon, i.e., an outer planar surface, to make the glass substrate thinner. The glass substrate in the present embodiment is made thinner to have a thickness of about 150 μm, for example, by the above-described thinning process.

Next, components connected to the liquid crystal panel 11 is described. As illustrated in FIG. 2, the driver 12 is constituted of an LSI chip having a drive circuit therein and operates on the basis of driving power and a reference potential supplied from a main board portion, which is a power source, through the rigid flexible board 20 to produce output signals by processing input signals relating to images supplied from the main board portion, which is a signal supply source, through the rigid flexible board 20, and the driver 12 outputs the output signals to the display area AA of the liquid crystal panel 11. The driver 12 has a horizontally elongated quadrilateral shape in plan view and is directly mounted on the non-display area NAA of the array substrate 11b of the liquid crystal panel 11, i.e., mounted by using COG (Chip On Glass) technology. The long side direction of the drivers 12 that are disposed along the edge LE extending in the long side direction of the liquid crystal panel 11 matches the X axis direction and the short side direction thereof matches the Y axis direction. The long side direction of the drivers 12 that are disposed along the edge SE extending in the short side direction of the liquid crystal panel 11 matches the Y axis direction and the short side direction thereof matches the X axis direction. The drivers 12 are arranged next to each other in the extending direction of the mounting region in the non-display area NAA with a space therebetween.

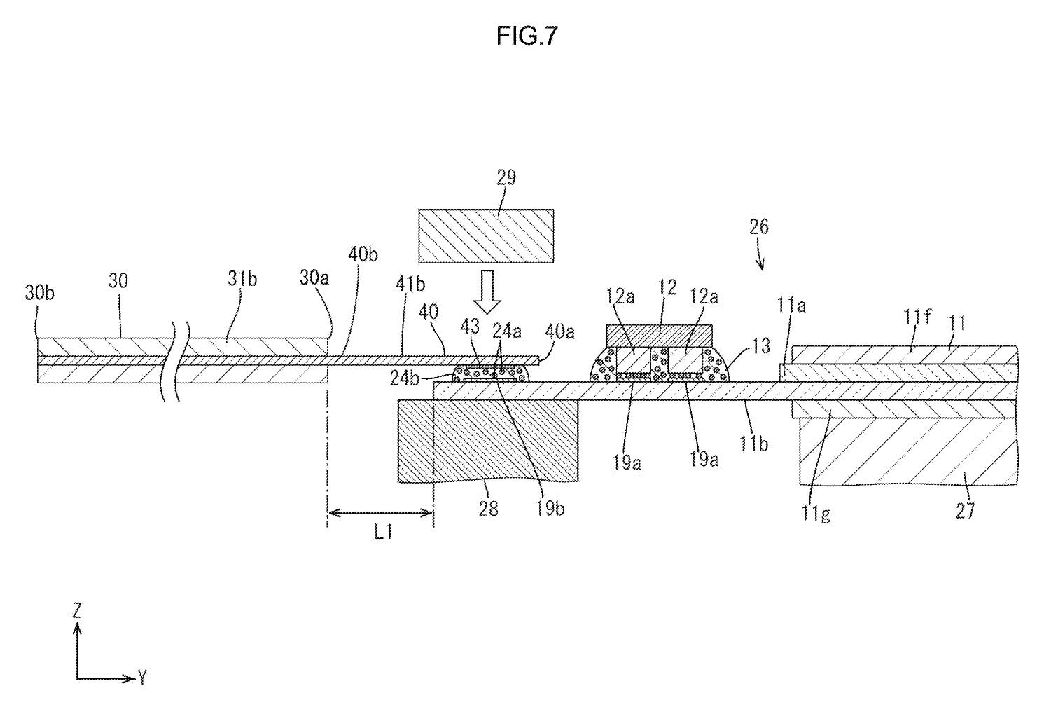

As illustrated in FIG. 7, on the non-display area NAA of the array substrate 11b on which the drivers 12 are mounted, panel-side driver input-output terminals 19a, which are connected to corresponding driver-side input-output terminals 12a included in the drivers 12, are disposed, and a panel-side output wiring line (not illustrated) for connecting an output of the panel-side driver input-output terminals 19a to the display area AA and a panel-side input wiring line (not illustrated) for connecting an input of the panel-side driver input-output terminals 19a to the rigid flexible board 20 are also disposed. A panel-side flexible board terminal 19b, which is connected to the rigid flexible board 20, is disposed at the end of the panel-side input wiring line adjacent to the rigid flexible board 20 (remote from the driver 20). Many panel-side flexible board terminals 19b are arranged along the edge LE (in the X axis direction) extending in the long side direction of the non-display area NAA of the array board 11b, which is connected to the rigid flexible board 20, with a space therebetween. The panel-side driver output-input terminals 19a and the panel-side flexible board terminals 19b are exposed to outside for connection with the drivers 12 and the rigid flexible board 20. The panel-side output wiring lines and the panel-side input wiring line portion are covered with an insulation film, which is not illustrated, over almost all area thereof.

The rigid flexible board 20 is directly connected to the non-display area NAA of the liquid crystal panel 11, as illustrated in FIG. 2, so as to be electrically connected thereto and is electrically connected to the main board included in the liquid crystal display device 10 through a wiring member, which is not illustrated. Various signals relating to images are sent from the main board to the rigid flexible board 20, and thus the signals are able to be supplied to the drivers 12 mounted on the liquid crystal panel 11. The rigid flexible board 20 is disposed along the edge LE of the non-display area NAA of the liquid crystal panel 11 to which the rigid flexible board 20 is attached. The width direction of the rigid flexible board 20 matches the arrangement direction (Y axis direction) in which the liquid crystal panel 11 and the rigid flexible board 20 are arranged. The longitudinal direction of the rigid flexible board 20 matches a direction (X axis direction) perpendicular to the arrangement direction of the liquid crystal panel 11 and the rigid flexible board 20 along the planar surface of the liquid crystal panel 11.

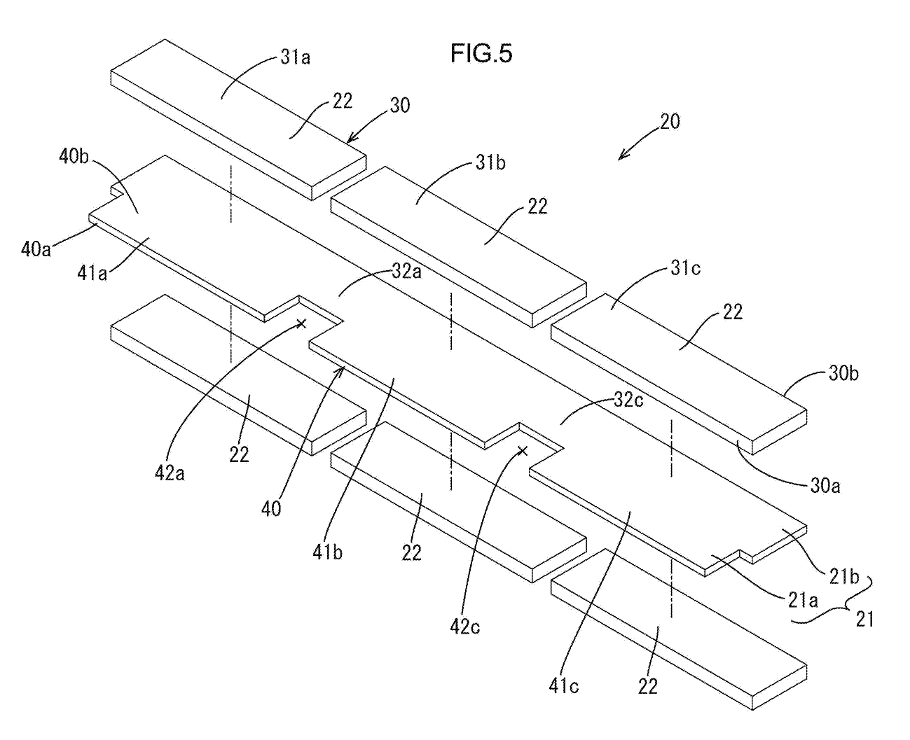

As illustrated in FIG. 5, the rigid flexible board 20 includes a flexible base member 21 having flexibility and rigid base members 22 having rigidity and almost no flexibility. The flexible base member 21 is a film formed of a synthetic resin material (polyimide-based resin, for example) having insulation properties and has a flexible-side wiring line routed on a surface of the film. The flexible base member 21 has an elongated comb-like overall shape. A portion 21a of the flexible base member 21 adjacent to the liquid crystal panel 11 in the short side direction (a portion constituting a flexible base portion 40, which is described later) is separated into three portions in the long side direction. A portion 21b of the flexible base member 21 remote from the liquid crystal panel 11 (a portion constituting the rigid board portion 30, which is described later) has a rectangular shape extending in the long side direction. A flexible-side terminal 43 connected to the liquid crystal panel 11 is disposed on one end of the flexible base member 21 adjacent to the liquid crystal panel 11 (remote from the rigid board portion 30) (see FIG. 7). The flexible base member 21 is more flexible than the rigid base member 22 and is readily subjected to deflection deformation or bending deformation.

As illustrated in FIG. 5, the rigid base member 22 includes a power source component, which is configured to supply driving power and a reference potential to the drivers 12, an electronic component (circuit component), which is configured to control transmission of input signals relating to images to the liquid crystal panel 11, and a rigid-side wiring line routed on the main surface thereof (all are not illustrated) on a substrate having a predetermined thickness, which is formed of phenolic paper or glass epoxy resin, for example. The rigid base member 22 has many via holes, which are not illustrated. The rigid-side wiring lines of the rigid base member 22 are electrically connected to the flexible-side wiring lines of the flexible base member 21 through the via holes. In this embodiment, three pairs of rigid base members 22 each having the flexible base member 21 therebetween are arranged along the edge LE of the liquid crystal panel 11 (in the longitudinal direction of the flexible base member 21). The rigid base member 22 is rigid with almost no flexibility, compared with the flexible base member 21, and is hardly subjected to deflection deformation or bending deformation.

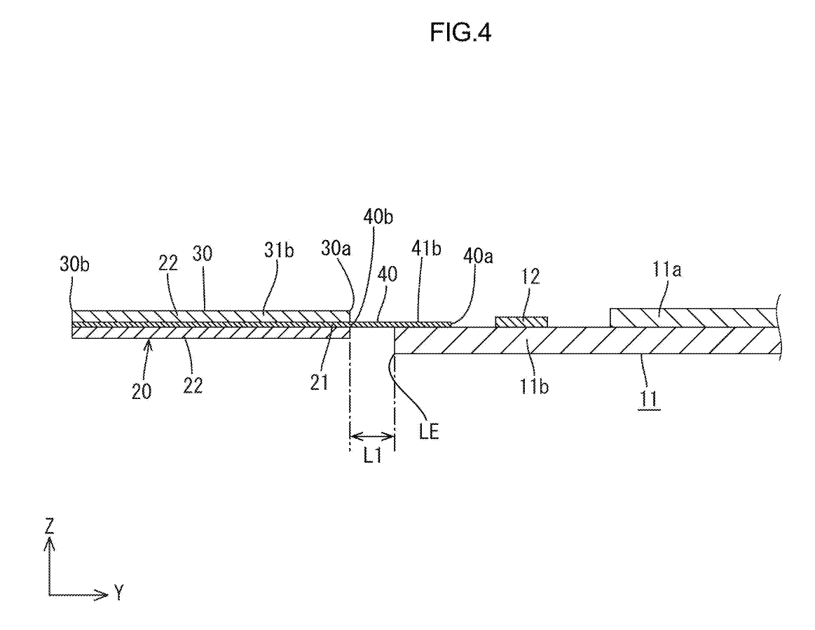

As illustrated in FIG. 4 and FIG. 5, the rigid flexible board 20 includes the rigid board portion 30 having a laminated structure, which includes the two rigid base members 22 and the portion 21b of the flexible base member 21 sandwiched between the rigid base members 22, and the flexible board portion 40. The flexible board portion 40 includes the portion 21a of the flexible base member 21, which is not sandwiched between the rigid base members 22. In other words, in the rigid flexible board 20, the rigid board portion 30 is integrally formed with the flexible board portion 40 such that the rigid base members 22 are disposed on the flexible base member 21 constituting the flexible board portion 40. In still other words, a portion of the rigid flexible board 20 adjacent to the liquid crystal panel 11 is the flexible board portion 40 and a portion thereof remote from the liquid crystal panel 11 is the rigid board portion 30. The flexible board portion 40 is attached to the non-display area NAA of the liquid crystal panel 11 at a first end 40a in the Y axis direction (a lower side in FIG. 1) and is connected to the rigid board portion 30 at a second end 40b (an upper side in FIG. 1). The flexible board portion 40 and the rigid board portion 30 are electrically connected to each other by flexible-side wiring lines of the flexible base member 21, which extend across the flexible board portion 40 and the rigid board portion 30. A rigid-side terminal, which is not illustrated, is disposed on the rigid board portion 30 to electrically connect the rigid board portion 30 and the main board of the liquid crystal display device 10 to each other through the rigid-side terminal. This configuration enables the rigid board portion 30 to transmit the signals to the liquid crystal panel 11 through the flexible board portion 40. In this embodiment, the rigid board portion 30 of the rigid flexible board 20 functions as the “signal supply board” and the flexible board portion 40 thereof functions as the “flexible board”.

As illustrated in FIG. 1, the flexible board portion 40 is separated along the edge LE of the liquid crystal panel 11. Specifically, the flexible board portion 40 is separated into three flexible portions 41a, 41b, and 41c along the edge LE of the liquid crystal panel 11 (in the longitudinal direction of the flexible base member 21). The flexible board portion 40 includes a space 42a between the flexible portion 41a and the flexible portion 41b and a space 42c between the flexible portion 41b and the flexible portion 41c. In this embodiment, the flexible board portion 40 including separated portions are described as an example, but the flexible board portion may be one integral portion extending over the entire area. Alternatively, the flexible board portion may be separated into two portions or four or more portions. The configuration and the number of flexible board portions may be suitably determined depending on the size, resolution, or the number of mounted terminals of the liquid crystal panel 11.

As illustrated in FIG. 1, the flexible board portion 40 is attached to the liquid crystal panel 11 at the end portions adjacent to the first end 40a over the substantially entire length of the edge LE with a space between the end portions. As illustrated in FIG. 7, the flexible-side terminal 43 on the first end 40a is thermocompression bonded to the panel-side flexible board terminal 19b on the liquid crystal panel 11 such that the flexible board portion 40 is electrically and mechanically connected to the liquid crystal panel 11. Specifically, an anisotropic conductive film (ACF) 24 including a plurality of conductive particles 27a made of a metal material and a thermosetting resin 27b having the conductive particles 27a therein in a dispersed state is disposed on the panel-side flexible board terminal 19b. The flexible-side terminal 43 is electrically connected to the panel-side flexible board terminal 19b through the conductive particles 24a. The thermosetting resin 24b in the cured state allows the flexible board portion 40 (the rigid flexible board 20) to be fixed to the liquid crystal panel 11. The flexible-side terminal 43 and the panel-side flexible board terminal 19b are connected to each other through the anisotropic conductive film 24 by mounting the flexible board portion 40 on the array substrate 11b by using a flexible board mounting apparatus 26. The step of mounting by using the flexible board mounting apparatus 26 is described later.

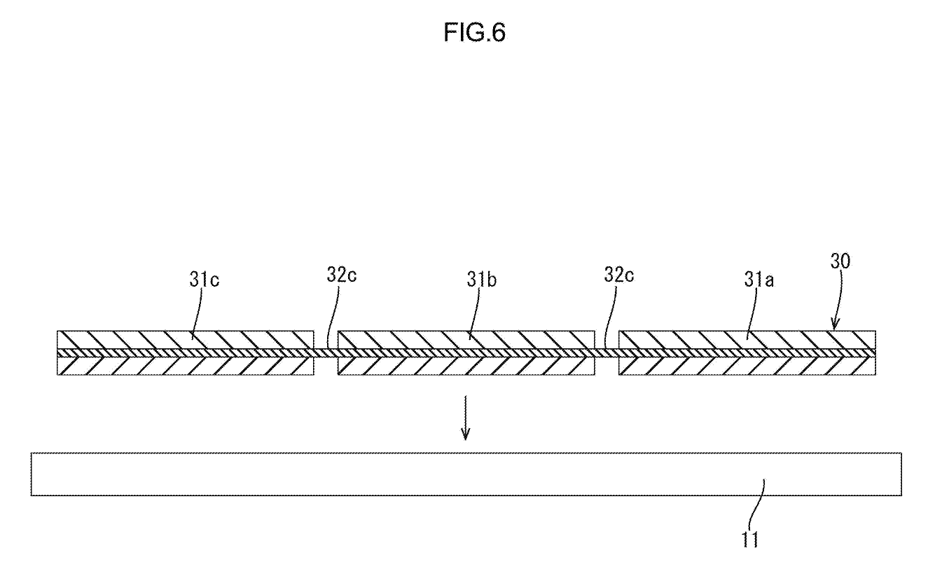

As illustrated in FIG. 5 and FIG. 6, the rigid board portion 30 includes three rigid portions 31a, 31b, and 31c, which are constituted of the two rigid base members 22 and the flexible base member 21 sandwiched between the rigid base members 22, and a low rigidity portion 32a and a low rigidity portion 32c, which are respectively located between the rigid portion 31a and the rigid portion 31b positioned next to each other and between the rigid portion 31b and the rigid portion 31c positioned next to each other and are constituted of the flexible base member 21. In other words, the rigid board portion 30 at least includes the rigid portion 31a (the rigid portion 31b), which has a higher rigidity than the flexible board portion 40, the rigid portion 31b (the rigid portion 31c), which is located next to the rigid portion 31a and has a higher rigidity than the flexible board portion 40, the low rigidity portion 32a (the low rigidity portion 32c), which is located between the rigid portion 31a and the rigid portion 31b (the rigid portion 31b and the rigid portion 31c) and has a lower rigidity than the rigid portion 31a and the rigid portion 31b.

As illustrated in FIG. 5 and FIG. 6, the rigid board portion 30 includes the three rigid portions 31a, 31b, and 31c, which are arranged along the edge LE of the liquid crystal panel 11, and the low rigidity portions 32a and 32c extending from the first edge 30a adjacent to the liquid crystal panel 11 to the second edge 30b remote from the liquid crystal panel 11 at positions between the rigid portions 31a, 31b, and 31c. In the rigid board portion 30, the rigid portion 31a (the rigid portion 31b) is connected to the flexible portion 41a (the flexible portion 41b) and the rigid portion 31b (the rigid portion 31c) is connected to the flexible portion 41b (the flexible portion 41c), and the low rigidity portion 32a (the low rigidity portion 32c) faces the space 42a (the space 42c). The rigid portions 31a, 31b, and 31c are electrically connected to each other through the respective low rigidity portions 32a and 32c (the flexible base member 21) located therebetween.

The liquid crystal display device 10 has recently increasingly demanded to have a smaller thickness and to have a frame with a smaller width. To meet the demand, the rigid flexible board 20 is disposed closer to the liquid crystal panel 11 such that the display area AA constitutes a high proportion of the overall size of the liquid crystal display device 10. Thus, as illustrated in FIG. 1 and FIG. 4, in the liquid crystal display device 10, the dimension L1 from the edge LE of the liquid crystal panel 11 to the rigid board portion 30 is small. The dimension L1 may only be about 2 mm when the frame is demanded to have a further smaller width for smartphones, for example. In this configuration, it is recognized that the rigid board portion 30 is heated to about 150 to 200° C., for example, by the heat generated during thermocompression bonding of the flexible board portion 40 to the liquid crystal panel 11, and the rigid board portion 40 of the small to medium sized liquid crystal display device 10 is thermally expanded by about a few millimeters. The flexible base member 21 and the rigid base member 22, which are included in the rigid flexible board 20, have different thermal expansion coefficients. In a rigid board portion of a conventional rigid flexible board having no low rigidity portion, a displacement due to thermal expansion occurring at two separate positions is absorbed by a displacement in a direction perpendicular to the planar surface thereof, leading to warping deformation (upward warping or downward warping) or corrugated deformation of the planer surface of the rigid board portion. In such a case, the deformed rigid board portion may deform the liquid crystal panel through the flexible board portion. If the liquid crystal panel 11 is deformed, the deformation may lead to display unevenness in the display area AA. Such a problem readily occurs particularly in the liquid crystal panel 11 having a smaller thickness and in the liquid crystal panel 11 having a smaller dimension L1, which is measured from the edge LE of the liquid crystal panel 11 to the rigid board portion 30.

Meanwhile, regarding this embodiment, i.e., the rigid board portion 30 of the rigid flexible board 20 having the low rigidity portions 32a and 32b, a flexible board mounting step of mounting the flexible board portion 40 on the liquid crystal panel 11 and an operation of the rigid flexible board 20 during the step are described. First, in the flexible board mounting step, the positions of the flexible-side terminal 43 and the panel-side flexible board terminal 19b are adjusted, and as illustrated in FIG. 6, the rigid flexible board 20 is mounted on the liquid crystal panel 11 (the array substrate 11b). At this time, the rigid board portion 30 of the rigid flexible board 20 is not subjected to deformation or the like and is substantially flat in the X axis direction. Then, as illustrated in FIG. 7, the liquid crystal panel 11 is disposed on a board retainer 27 and a board receiver 28, which are components of the flexible board mounting apparatus 26. This allows a portion of the array substrate 11b having the panel side flexible board terminal 19b thereon to be supported by the board receiver 28 at the rear surface thereof and the other portion than the above-described portion is strongly held by the board retainer 27 due to vacuum contact over a large area. A pressure portion 29 is moved down toward the rigid flexible board 20 and a pressing pressure and heat are applied to the flexible board portion 40 by the pressure portion 29 when the pressure portion 29 contacts with the flexible board portion 40. After the application of pressure and heat for a predetermined time by the pressure portion 29, the thermocompression bonding of the rigid flexible board 20 (the flexible board portion 40) to the liquid crystal panel 11 is completed.

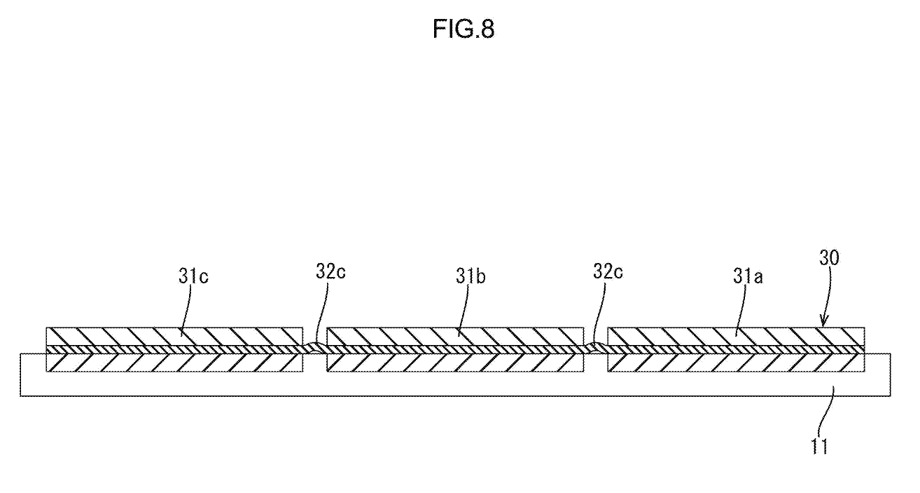

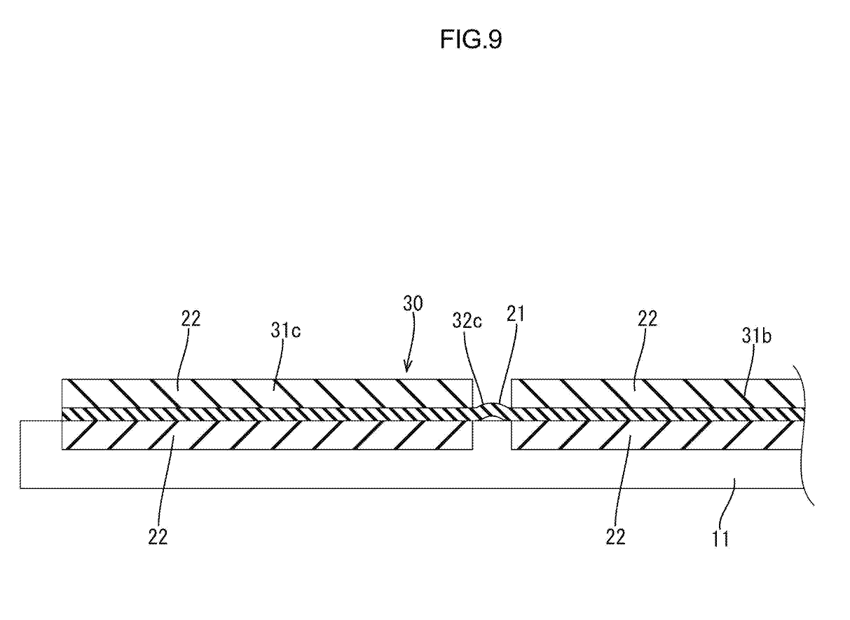

In the flexible board mounting step, the heat from the pressure portion 29 is transferred to the rigid board portion 30 through the flexible base member 21 or as radiant heat. Then, the flexible base member 21 and the rigid base member 22 included in the rigid board portion 30 are subjected to the thermal expansion depending on the respective thermal expansion coefficient. The rigid board portion 30 deforms due to the difference in the thermal expansion coefficient between the flexible base member 21 and the rigid base member 22. The rigid flexible board 20 has an elongated shape extending along the edge LE of the liquid crystal panel 11 for its function, and the rigid board portion 30 particularly readily deforms (warping deformation or wave deformation) in the longitudinal direction thereof. Furthermore, the rigid flexible board 20 is connected to the liquid crystal panel 11 along the edge LE of the liquid crystal panel 11, and thus force acting on the liquid crystal panel 11 due to the deformation of the rigid flexible board 20 in the longitudinal direction may cause a problem. Here, since the low rigidity portions 32a and 32c have a lower rigidity than the rigid portions 31a, 31b, and 31c, i.e., the low rigidity portions 32a and 32c are configured to be relatively readily deformed, the low rigidity portion 32 deforms to absorb the displacement between the rigid portion 31a and the rigid portion 31b and the displacement between the rigid portion 31b and the rigid portion 31c (FIG. 9). As illustrated in FIG. 8, this reduces the displacement in the direction perpendicular to the planar surface at a position between the rigid portion 31a and the rigid portion 31b and at a position between the rigid portion 31b and the rigid portion 31c. Furthermore, the low rigidity portions 32a and 32b allow the rigid portions 31a, 31b, and 31c themselves to be expanded in the longitudinal direction (direction along the edge LE of the liquid crystal panel 11), and thus the deformation in the direction perpendicular to the planar surface is unlikely to occur. In other words, in the rigid board portion 30, since the deformation of the portions other than the low rigidity portions 32a and 32b is reduced, the rigid board portion 30 has a flat outer shape as a whole.

In the rigid board portion 30, the rigid portions 31a, 31b, and 31c are rigid and force the array substrate 11b included in the liquid crystal panel 11 to deform in conformity with the rigid board portion 30 (the rigid portions 31a, 31b, and 31c) through the flexible portions 41a, 41b, and 41c of the flexible board portion 40. This force causes a problem particularly in the array substrate 11b constituting of a thin glass substrate as in the present embodiment. In the present embodiment, since the amounts of displacement in the direction perpendicular to the planar surface at the positions between the rigid portion 31a and the rigid portion 31b and between the rigid portion 31b and the rigid portion 31c are reduced, the portions of the array substrate 11b to which the flexible portion 41a, the flexible portion 41b, and the flexible portion 41c are connected are unlikely to be deformed. In addition, since the rigid portions 31a, 31b, and 31c are configured to be less deformed, the portions to which the flexible portions 41a, 41b, and 41c are connected are unlikely to be locally deformed in conformity with the rigid portions 31a, 31b, and 31c. This enables the planar surface of the array substrate 11b to have high flatness.

As described above, the liquid crystal display device 10 in this embodiment includes the liquid crystal panel 11 having the display area AA capable of displaying an image and the non-display area NAA outside the display area AA, the flexible board portion 40 having flexibility and connected to the non-display area NAA at the first end 40a thereof, and the rigid board portion 30 connected to the second end 40b of the flexible board portion 40 opposite the first end 40a and configured to supply signals to the liquid crystal panel 11 through the flexible board portion 40. The rigid board portion 30 at least includes the rigid portion 31a (the rigid portion 31b) having a higher rigidity than the flexible board portion 40, the rigid portion 31b (the rigid portion 31c) located next to the rigid portion 31a (the rigid portion 31b) and having a higher rigidity than the flexible board portion 40, and the low rigidity portion 32a (the low rigidity portion 32c) located between the rigid portion 31a and the rigid portion 31b (the rigid portion 31b and the rigid portion 31c) and having a lower rigidity than the rigid portion 31a and the rigid portion 31b (the low rigidity portion 31b and the low rigidity portion 31c).

In this embodiment, the displacement between the rigid portion 31a and the rigid portion 31b (the rigid portion 31b and the rigid portion 31c) is absorbed by the deformation of the low rigidity portion 32a (the low rigidity portion 32c), reducing the deformation of the rigid portion 31a and the rigid portion 31b (the rigid portion 31b and the rigid portion 31c). This reduces the force applied from the rigid board portion 30 to the liquid crystal panel 11 through the flexible board portion 40, which is generated by the deformation of the rigid portion 31a and the rigid portion 31b (the rigid portion 31b and the rigid portion 31c), reducing the deformation of the liquid crystal panel 11 caused by the deformation of a rigid section of the rigid board portion 30.

In this embodiment, the non-display area NAA extends along the edge LE of the liquid crystal panel 11 and the rigid portion 31a and the rigid portion 31b (the rigid portion 31b and the rigid portion 31c) of the rigid board portion 30 are located next to each other along the edge LE of the liquid crystal panel 11. This configuration reduces the deformation of the rigid board portion 30 in a direction along the edge LE of the liquid crystal panel 11 and thus reliably reduces the deformation of the liquid crystal panel 11.

Furthermore, in this embodiment, the flexible board portion 40 at least includes the flexible portions 41a, the flexible portion 41b, and the flexible portion 41c, which are separately located next to each other along the edge LE of the liquid crystal panel 11, and further includes the spaces 42a and 42c between the flexible portion 41a and the flexible portion 41b (the flexible portion 41b and the flexible portion 41c). The rigid portion 31a (the rigid portion 31b) and the rigid portion 31b (the rigid portion 31c) of the rigid board portion 30 are respectively connected to the flexible portion 41a (the flexible portion 41b) and the flexible portion 41b (the flexible portion 41c). The low rigidity portion 32a (the low rigidity portion 32c) faces the space 42a (the space 42c). This configuration enables the rigid board portion 30 to be connected to the flexible board portion 40 at the rigid portion 31a (the rigid portion 31b) and the rigid portion 31b (the rigid portion 31c) of the rigid board portion 30, where the deformation is less likely to occur, and reduces the influence of the deformation of the low rigidity portion 32a (the low rigidity portion 32c) on the liquid crystal panel 11 through the flexible board portion 40.

Furthermore, in this embodiment, the flexible board portion 40 is connected to the non-display area NAA by the thermocompression bonding. The rigid board portion 30 is integrally formed with the flexible board portion 40 by stacking the rigid base member 22 on the flexible base member 21 constituting the flexible board portion 40. The rigid base member 22 has a higher rigidity than the flexible base member 21. The low rigidity portions 32a and 32c are at least constituted of a portion of the flexible base member 21. This configuration enables the rigid flexible board 20 integrally including the flexible board portion 40 and the rigid board portion 30 to reliably have the low rigidity portions 32a and 32c without the need for a separate flexible base member, for example. The deformation of the rigid board portion 30 caused by the heat generated during the thermocompression bonding of the flexible board portion 40 to the liquid crystal panel 11 is absorbed by the low rigidity portions 32a and 32c.

In particular, when the configuration relating to the rigid flexible board 20 is employed, the connection between the terminals on the signal supply board (the rigid board portion 30) and the terminals on the flexible board (the flexible board portion 40) may be eliminated, leading to an improvement in the reliability of the connection and the downsize (merit). However, since the connection area between the flexible base member 21 and the rigid base member 22 is large, this configuration may readily cause a problem of deformation of the rigid board portion 30 (demerit). In this embodiment, the low rigidity portions 32a and 32c reduce the demerit of the rigid flexible board 20 and enjoy the merit of the employment of the rigid flexible board 20.

Furthermore, in this embodiment, the low rigidity portions 32a and 32c extend from the first edge 30a of the rigid board portion 30 to the second edge 30b thereof. The low rigidity portions 32a and 32c constituted of the flexible base member 21 enable the rigid portion 31a and the rigid portion 31b (the rigid portion 31b and the rigid portion 31c) to be connected to each other through the flexible base member 21. This enables the low rigidity portions 32a and 32c to extend from the first edge 30a of the rigid board 30 to the second edge 30b thereof, which is difficult if the low rigidity portion is constituted of a slit or the like in the signal supply board, for example. Then, with this configuration, the displacement between the rigid portion 31a and the rigid portion 31b (the rigid portion 31b and the rigid portion 31c) is uniformly absorbed by the low rigidity portions 32a and 32c from the first edge 30a of the rigid board 30 to the second edge 30b, which is preferable.

Furthermore, in this embodiment, the liquid crystal panel 11 includes the liquid crystal layer 11c sealed between the two substrates 11a and 11b. Such a display device has various uses as the liquid crystal display device 10 and is applicable to various electronic devices such as a mobile phone, a smart phone, and a tablet computer, for example.

### Second Embodiment

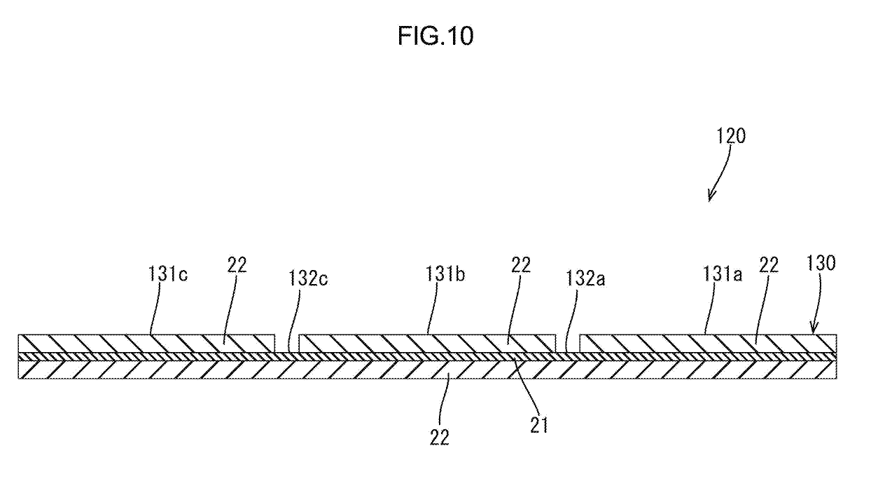

A second embodiment of the present invention is described with reference to FIG. 10. In the second embodiment, the configuration of a rigid board portion 130 of a rigid flexible board 120 is different from the rigid flexible board 20 in the above-described first embodiment. The configurations, operations, and effects similar to those in the first embodiment are not described.

In this embodiment, the rigid base members 22 sandwich the flexible base member 21. One of the rigid base members 22 on a first film surface of the flexible base member 21 (a lower side in FIG. 10) has an oblong shape extending along the edge LE of the liquid crystal panel 11 (in the longitudinal direction of the flexible base member 21). Three of the rigid base members 22 on a second film surface of the flexible base member 21 (an upper side in FIG. 10) are disposed next to each other along the edge LE of the liquid crystal panel 11 (in the longitudinal direction of the flexible base member 21).

The rigid board portion 130 includes three rigid portions 131a, 131b, and 131c each constituted of the rigid base members 22 in two layers with the flexible base member 21 therebetween and the flexible base member 21 sandwiched by the rigid base members 22, and low rigidity portions 132a and 132c each constituted of the rigid base member 22 in one layer and the flexible base member 21. The low rigidity portions 132a and 132c are respectively located between the rigid portion 131a and the rigid portion 131b, which are positioned next to each other, and the rigid portion 131b and the rigid portion 131c, which are positioned next to each other. In other words, in the first embodiment, the low rigidity portion 32a and the low rigidity portion 32c are constituted of the flexible base member 21 alone, but the low rigidity portion 132a and the low rigidity portion 132c are constituted of the flexible base member 21 and the rigid base member 22 in one layer on the first film surface (a lower side in FIG. 10) of the flexible base member 21 in this embodiment. Thus, the low rigidity portions 132a and 132c in this embodiment have a lower rigidity than the rigid portions 131a, 131b, and 131c, but have a higher rigidity than the low rigidity portions 32a and 32c in the first embodiment. This configuration makes the rigid flexible board 120 to be readily handled during mounting of various electronic components on the rigid board portion 130, for example, compared with the rigid flexible board portion 20 in the first embodiment.

The inventor of this application conducted a comprehensive study and found that the low rigidity portions 132a and 132c having a rigidity not so low (not so deformable) as that of the flexible base member 21 included in the flexible board portion 40 but lower than that of the other portions of the rigid board portion 130 (the rigid portion 131a, the rigid portion 131b, and the rigid portion 131c) even by a small amount reduce the deformation of the rigid board portion 130. The operations and effects of the rigid board portion 130 are similar to those in the first embodiment and are not described.

### Third Embodiment

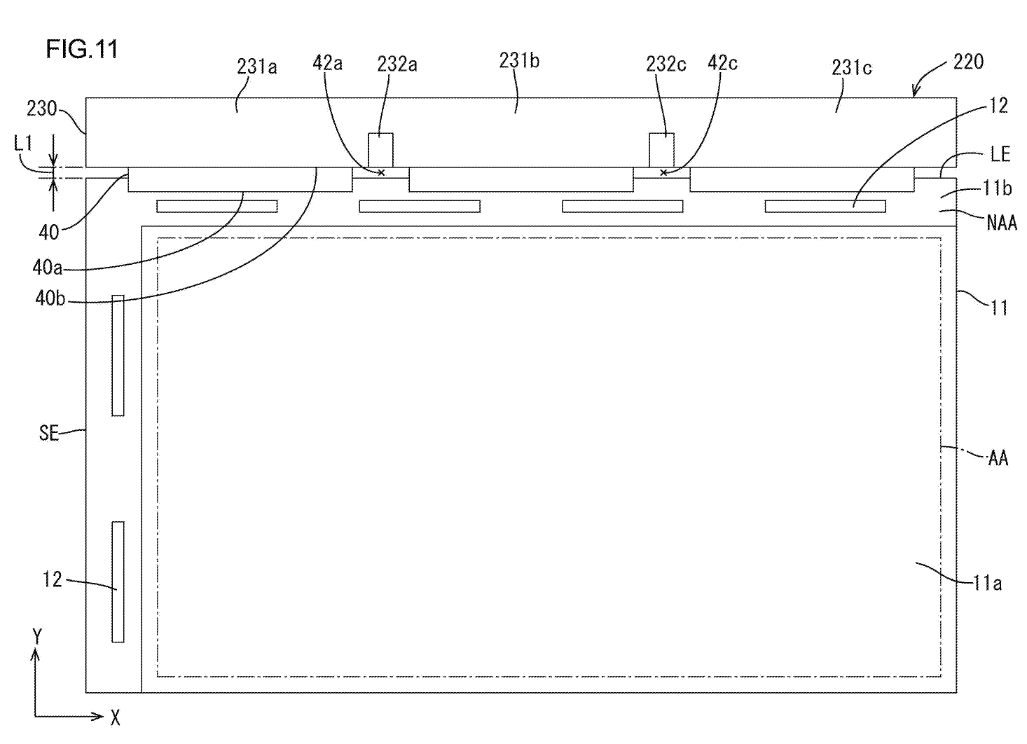

A third embodiment of the present invention is described with reference to FIG. 11. In the third embodiment, the configuration of a rigid board portion 230 of a rigid flexible board 220 is different from the rigid flexible board 20 in the above-described first embodiment. The configurations, operations, and effects similar to those in the first embodiment are not described.

In this embodiment, the two rigid base members 22 sandwich the flexible base member 21. Each of the rigid base members 22 has an oblong overall shape extending along the edge LE of the liquid crystal panel 11 (in the longitudinal direction of the flexible base member 21) and the oblong shape has two cutouts at the first edge 30a of the rigid board portion 230 to be in a comb-like shape.

The rigid board portion 230 includes three rigid portions 231a, 231b, and 231c, which are constituted of the teeth-shaped portions of the two rigid base members 22 and the portions of the flexible base member 21 sandwiched therebetween, and low rigidity portions 232a and 232c, which are constituted of the flexible base member 21. The low rigidity portions 232a and 232c are respectively located between the rigid portion 231a and the rigid portion 231b positioned next to each other and between the rigid portion 231b and the rigid portion 231c positioned next to each other.

The inventor of the present application conducted a comprehensive study and found that, like the low rigidity portion 232a and 232c, the low rigidity portion not extending from one edge to the other edge of the rigid board portion and extending along only a portion of the rigid board portion is capable of reducing the deformation of the rigid board portion 230. The operations and effects of the rigid board portion 240 are similar to those in the first embodiment and are not described.

### Fourth Embodiment

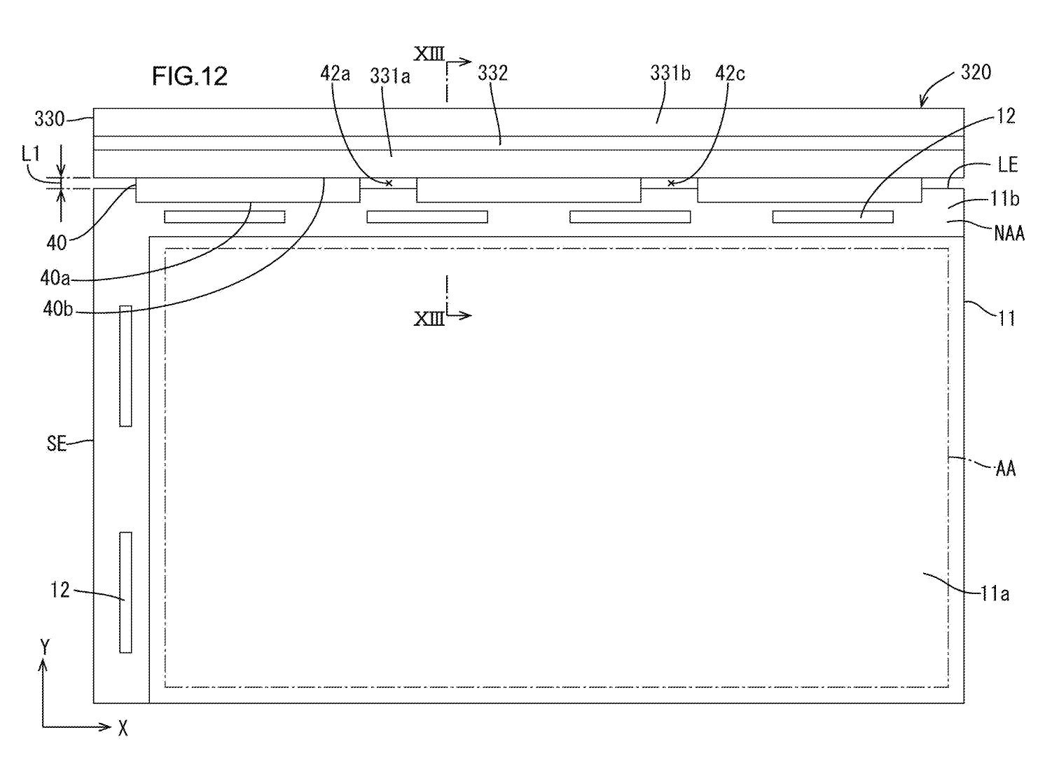

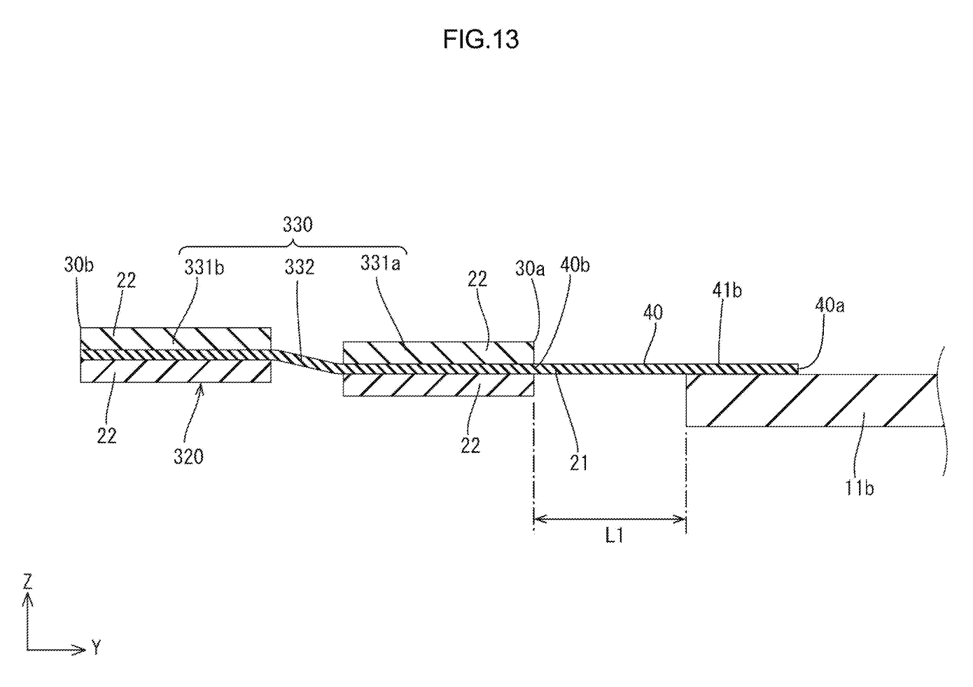

A fourth embodiment of the present invention is described with reference to FIG. 12 and FIG. 13. In the fourth embodiment, the configuration of a rigid board portion 330 of a rigid flexible board 320 is different from the rigid flexible board 20 in the above-described first embodiment. The configurations, operations, and effects similar to those in the above-described first embodiment are not described.

In this embodiment, two pairs of the two rigid base members 22, each of which sandwich the flexible base member 21, are disposed in an arrangement direction in which the rigid flexible board 320 and the liquid crystal panel 11 are arranged (the short side direction of the flexible base member 21, Y axis direction).

The rigid board portion 330 includes two rigid portions 331a and 331b, which are constituted of the two rigid base members 22 and the flexible base member 21 sandwiched therebetween, and a low rigidity portion 332a, which is located between the rigid portion 331a and the rigid portion 331b positioned next to each other and is constituted of the flexible base member 21. In other words, the low rigidity portion 332a extends in parallel to the edge LE of the liquid crystal panel 11 (to which the flexible board portion 40 is connected) from one end to the other end in the longitudinal direction of the rigid board portion 330. The rigid board portion 330 is connected to the flexible board portion 40 (the flexible portion 41a, the flexible portion 41b, and the flexible portion 41c) at the first edge 30a of the rigid portion 331a. The rigid portion 331a and the rigid portion 331b are electrically connected to each other through the low rigidity portion 332a located therebetween.

In this embodiment, a portion of the rigid board portion 330 which applies force to the liquid crystal panel 11, i.e., the dimension of the rigid portion 331a in the Y axis direction, is small compared with a configuration, for example, in which a rigid base member extends over the entire area of the rigid board portion and force is applied to the liquid crystal panel 11 by the entire portion thereof. Thus, the rigidity of the portion is reduced. This reduces the force itself to be applied from the rigid board portion 330 to the liquid crystal panel 11. A component that may readily cause local deformation (for example, high-voltage densely arranged electrically conducting paths or amounting component generating a large amount of heat) may be disposed on the rigid board portion 330. In such a case, the component is disposed on the rigid board portion 331b such that the low rigidity portion 332a absorbs the deformation of the rigid board portion 331b. This reduces that the deformation of the rigid board portion 331b affects the rigid portion 331a (see FIG. 13).

### Fifth Embodiment

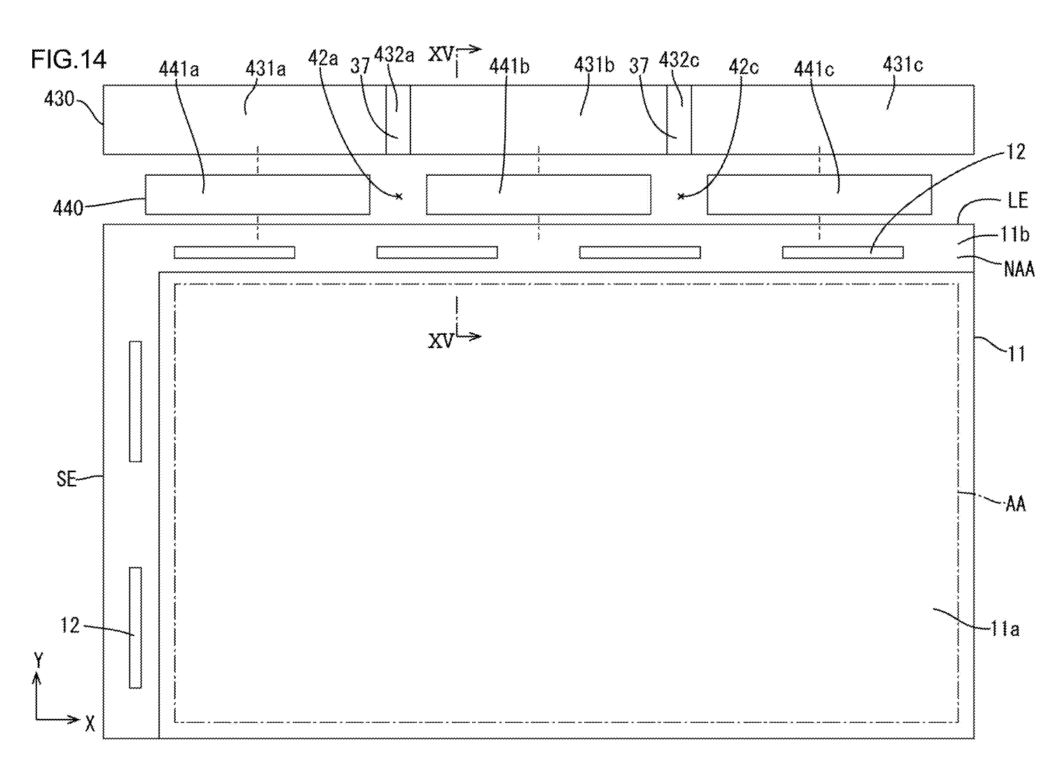

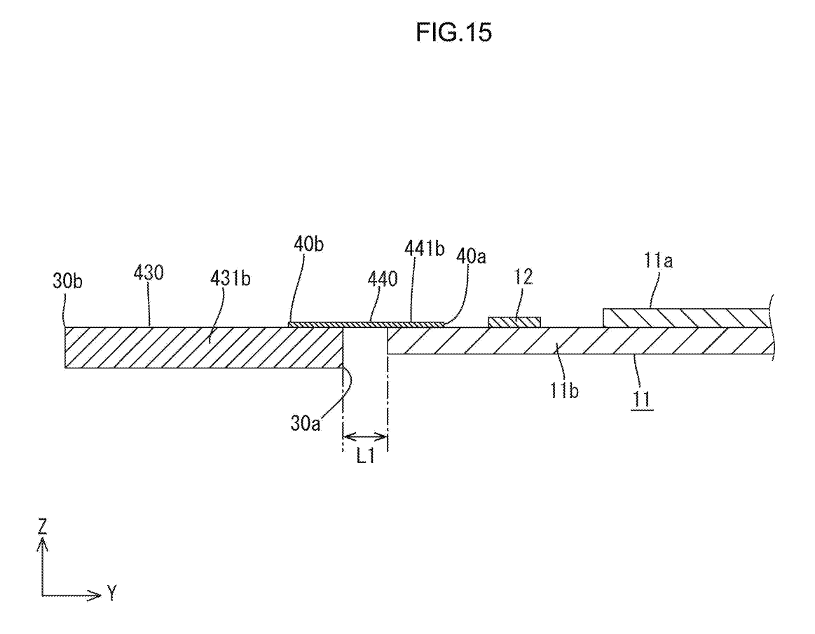

A fifth embodiment of the present invention is described with reference to FIG. 14 and FIG. 15. In the fifth embodiment, instead of the rigid flexible board described in the first embodiment, a rigid board (signal supply board) 430 and a flexible board 440, which are separate components, are included. The configurations, operations, and effects similar to those in the above-described first embodiment are not described.

The flexible board 440 is formed of a flexible base member having flexibility. The flexible base member is a film formed of a synthetic resin material having insulation properties (such as a polyimide-based resin) and has a flexible-side wiring pattern routed on a film surface thereof. The flexible board 440 includes separated three flexible portions 441a, 441b, and 441c each having a rectangular shape. The flexible side panel terminal 43, which is connected to the liquid crystal panel 11, is disposed on the first end 40a of the flexible board 440 adjacent to the liquid crystal panel 11 (remote from the rigid board 430).

The rigid board 430 includes three rigid portions 431a, 431b, and 431c and low rigidity portions 432a and 432c constituted of a rigid board side flexible base member (signal supply board side flexible base member) 37. The low rigidity portions 432a and 432c are respectively located between the rigid portion 431a and the rigid portion 431b positioned next to each other and between the rigid portion 431b and the rigid portion 431c positioned next to each other. In each of the rigid portion 431a, the rigid portion 431b, and the rigid portion 431c, a power component, which is configured to supply driving power and a reference potential to the drivers 12, and an electronic component (circuit component), which is configured to control the transmission of input signals relating to images to the liquid crystal panel 11, are mounted on a rigid base board having a predetermined thickness and formed of phenolic paper or glass epoxy resin, for example, and a rigid side wiring pattern (all are not illustrated) is routed on a main surface thereof. In other words, the rigid portion 431a, the rigid portion 431b, and the rigid portion 431c each have a configuration of a so-called printed wiring board. The rigid board side flexible base member 37 of the low rigidity portion 432a (the low rigidity portion 432c) is a film formed of a synthetic resin material having insulation properties (such as a polyimide-based resin) and has a low rigidity portion side wiring line routed on the film surface such that the rigid portions 431a and 431b (the rigid portions 431b and 431c) are electrically connected to each other. Ends of the low rigidity portion wiring line have low rigidity portion side terminals (not illustrated) configured to be connected to the rigid portion 431a and the rigid portion 431b (the rigid portion 431b and the rigid portion 431c), and are connected to rigid portion side terminals (not illustrated) of the rigid portion 431a and the rigid portion 431b (the rigid portion 431b and the rigid portion 431c) through an anisotropic conductive film. In this embodiment, the low rigidity portion 432a and the low rigidity portion 432c are separate components, but the low rigidity portion 432a and the low rigidity portion 432c may be an integral component.

A step of mounting the flexible board 440 on the liquid crystal panel 11 (a flexible board mounting step) and a step of mounting the rigid board 430 on the flexible board 440 (a rigid board mounting step) in this embodiment are described. First, in the flexible board mounting step, a first end 40a of each of the three flexile portions 441a, 441b, and 441c is positioned on the non-display area NAA of the liquid crystal panel 11 and is thermally bonded thereto by using a flexible board mounting apparatus in a similar way to the first embodiment. Next, in the rigid board mounting step, the rigid board 430 is positioned on the same side as the liquid crystal panel 11 (the lower side) in relation to the second end 40b of the flexible board 440, and a rigid board side flexible terminal on the first edge 30a of the rigid board 430 is connected to the flexible board side rigid terminal on the flexible board 440 through an anisotropic conductive film. At this time, a rigid board mounting apparatus having a similar configuration to the flexible board mounting apparatus is used to thermally bond the rigid board 430 to the flexible board 440 in a similar way to the flexible board mounting apparatus. The flexible board mounting step and the rigid board mounting step may be sequentially performed in this order or may be sequentially performed in a reverse order.

In this embodiment, since the rigid board 430 includes the low rigidity portions 432a and 432c, the deformation of the rigid board 430 caused by the heat during the thermocompression bonding of the rigid board 430 to the flexible board 440 is absorbed by the low rigidity portions 432a and 432c of the rigid board 430. Furthermore, since the rigid board 430 and the flexible board 440 are separate members, the connection area between the flexible base member and the rigid base member is limited to the first edge 30a of the rigid board 430. This reduces the deformation of the rigid board 430 itself compared with the rigid board portion of the rigid flexible board, for example, in which the connection area between the flexible base member and the rigid base member extends substantially over the entire area of the surface of the rigid board portion.

In this embodiment, the low rigidity portions 432a and 432c extend from the first edge 30a of the rigid board 430 adjacent to the liquid crystal panel 11 to the second edge 30b remote from the liquid crystal panel 11. The low rigidity portion 432a (the low rigidity portion 432c) formed of the rigid board side flexible base member 37 allows the connection between the rigid portion 431a and the rigid portion 431b (the rigid portion 431b and the rigid portion 431c) through the rigid board side flexible base member 37, enabling the low rigidity portions 432a and 432c to extend from the first edge 30a to the second edge 30b of the rigid board, which is difficult in the low rigidity portion constituted of a slit in the rigid board, for example. This configuration enables the low rigidity portion 432a (the low rigidity portion 432c) to uniformly absorb the displacement between the rigid portion 431a and the rigid portion 431b (the rigid portion 431b and the rigid portion 431c) from the first edge 30a of the rigid board portion 430 to the second edge 30b, which is preferable.

### Sixth Embodiment

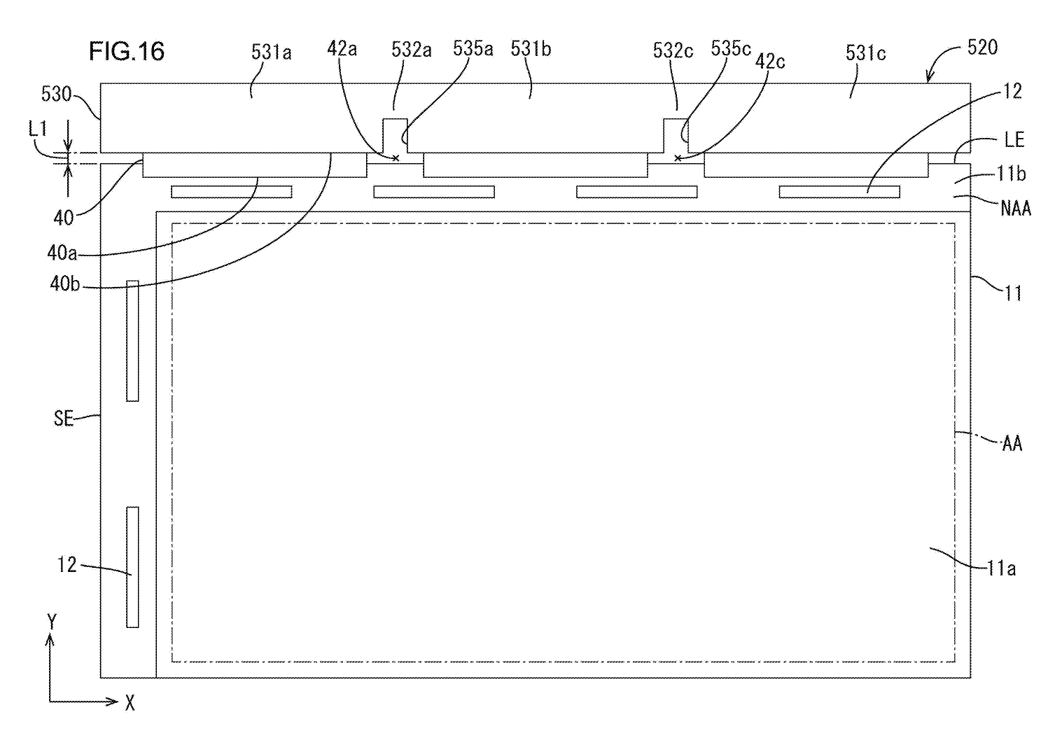

A sixth embodiment of the present invention is described with reference to FIG. 16. In the sixth embodiment, the configuration of a rigid board portion 530 of a rigid flexible board 520 is different from the rigid flexible board 20 in the above-described first embodiment. The configurations, operations, and effects similar to those in the above-described first embodiment are not described.

In this embodiment, as in the third embodiment, two rigid base members 22 sandwich the flexible base member 21. Each of the two rigid base members 22 has an oblong overall shape extending along the edge LE of the liquid crystal panel 11 (in the longitudinal direction of the flexible base member 21) and the oblong shape has two cutouts at the first edge 30a of the rigid board portion 530 to be in a comb-like shape. Furthermore, in this embodiment, unlike the third embodiment, the portion 21b of the flexible base member 21 remote from the liquid crystal panel 11 is configured to have the same shape as the rigid base member 22. In other words, the rigid board portion 530 includes slits 535a and 535c extending therethrough in the thickness direction. The rigid board portion 530 has a rectangular overall shape and has the slits 535a and 535c, which are cutouts, at the first edge 30a. In the rigid board portion 530, the slit 535a and the slit 535c are respectively located at positions close to the space 42a and the space 42c.

Low rigidity portions 532a and 532c are obtained by forming the slits 535a and 535c in the rigid board portion 530. Specifically, the low rigidity portion 532a and the low rigidity portion 532c each have a smaller width in the Y axis direction (about a half in this embodiment) than portions of the rigid board portion 530 not having the slits 535a and 535c (the rigid portion 531a, the rigid portion 531b, and the rigid portion 531c), and thus have lower rigidity. The rigidity of the low rigidity portions 532a and 532c are suitably adjusted by changing the size of the slits 535a and 535c.

Thermal expansion of the rigid board portion 530 may occur during mounting of the rigid board portion 520 on the liquid crystal panel 11. In such a case, the low rigidity portions 532a and 532c deform to absorb the displacement and deformation of the rigid portion 531a, the rigid portion 531b, and the rigid portion 531c. At this time, stress concentrates on connection portions between the low rigidity portions 532a and 532c and the corresponding rigid portion 531a, 531b, and 531c, accelerating the deformation of the low rigidity portions 532a and 532c and reducing the displacement and deformation between the rigid portion 531a, the rigid portion 531b, and the rigid portion 531c. The other operations of the low rigidity portions 532a and 532c for reducing the deformation of the rigid board portion 530 are similar to those in the first embodiment and are not described.

In this embodiment, since the low rigidity portions 532a and 532c are obtained by forming the slits 535a and 535c in the rigid board portion 530, the low rigidity portions 532a and 532c are readily formed, which is preferable. In addition, since the connections between the rigid portion 531a, the rigid portion 531b, and the rigid portion 531c are made by using the same wiring lines on the rigid base member 22 of the low rigidity portions 532a and 532c, for example, a configuration for connection between the rigid base member 22 and the flexible base member 21 is not required.

Furthermore, in this embodiment, since the slits 535a and 535c are cutouts at the first edge 30a of the rigid board portion 530, the low rigidity portions 532a and 532c readily absorb the deformation at the first edge 30a of the rigid board portion 530, and thus the force applied from the rigid board portion 530 to the liquid crystal panel 11 through the flexible board portion 40 is reliably reduced.

### Seventh Embodiment

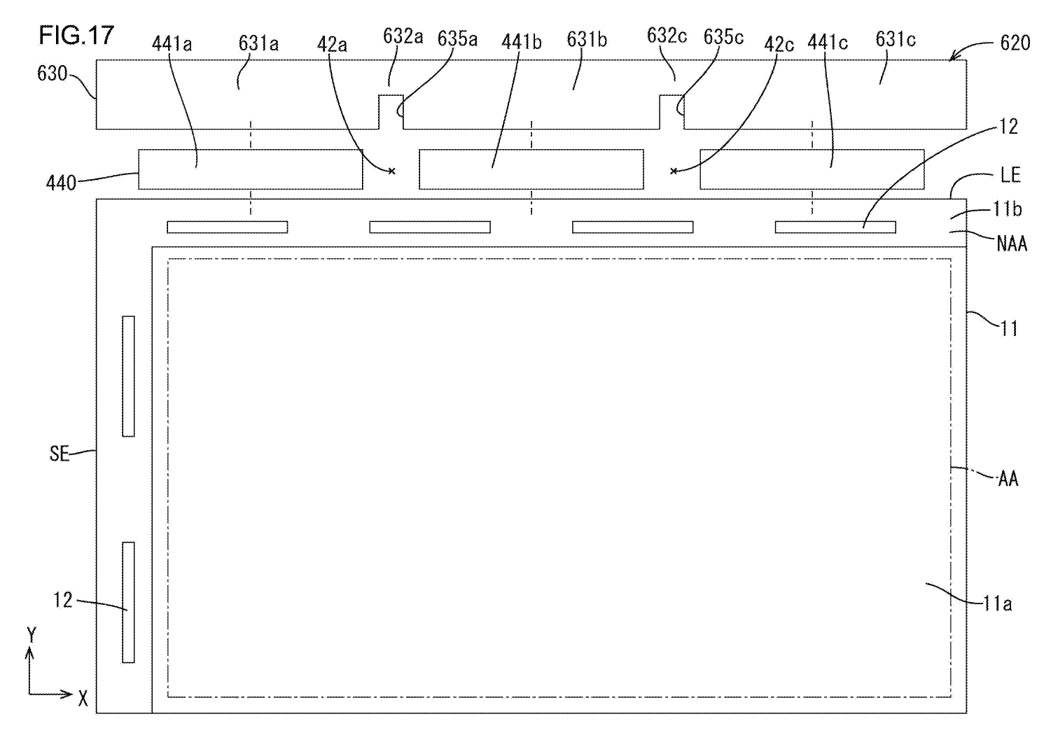

A seventh embodiment of the present invention is described with reference to FIG. 17. In the seventh embodiment, instead of the rigid flexible board described in the sixth embodiment, a rigid board (a signal supply board) 630 and a flexible board 440, which are separate components, are included. The configurations, operations, and effects similar to those in the above-described sixth embodiment are not described.

The rigid board 630 has a configuration of a so-called printed wiring board and has a rectangular overall shape and has slits 635a and 635c, which are cutouts, at the first edge 30a to provide low rigidity portions 635a and 635c. The rigid portion 631a, the rigid portion 631b, and the rigid portion 631c have the configuration similar to those of the rigid portions 431a, the rigid portion 431b, and the rigid portion 431c in the fifth embodiment and are not described. In addition, the operations of the low rigidity portions 635a and 635c are similar to those of the low rigidity portions 532a and 532c in the sixth embodiment and are not described.

### Eighth Embodiment

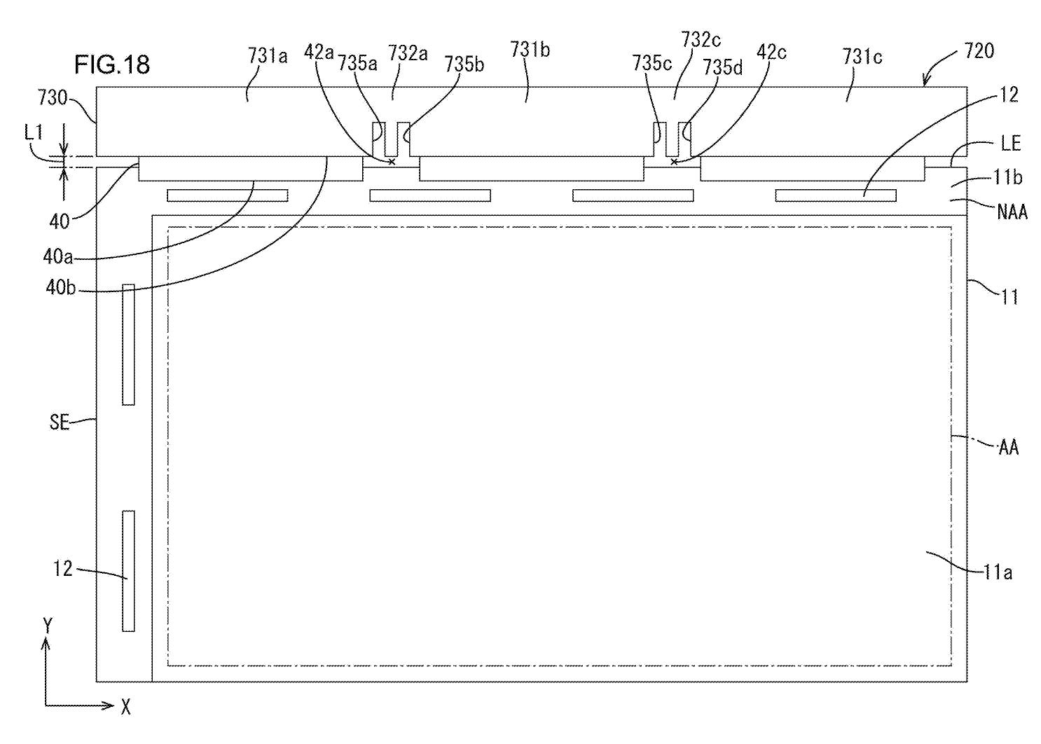

An eighth embodiment of the present invention is described with reference to FIG. 18. In the eighth embodiment, the configuration of a rigid board portion 730 of a rigid flexible board 720 is different from the rigid flexible board 520 in the above-described sixth embodiment. The configurations, operations, and effects similar to those in the above-described sixth embodiment are not described.

The rigid board portion 730 in this embodiment includes a plurality (two in this embodiment) of slits 735a and 735b (slits 735c and 735d) located close to each other and in parallel to each other, unlike the slit 535a (the slit 535c) in the sixth embodiment. With this configuration, the displacement in the rigid board portion 730 in an arrangement direction (X axis direction) in which the slit 735a and the slit 735b (the slit 735c and the slit 735d) are arranged is reliably absorbed. In addition, compared with a configuration in which one cutout extends over the area including the plurality of slits, the rigid board portion 730 readily has a larger surface area in an extending direction of the slits 735a and 735b (the slits 735c and 735d), readily enhancing the rigidity thereof. The number of slits located in parallel to each other is not limited to two and may be three or more.

### Ninth Embodiment

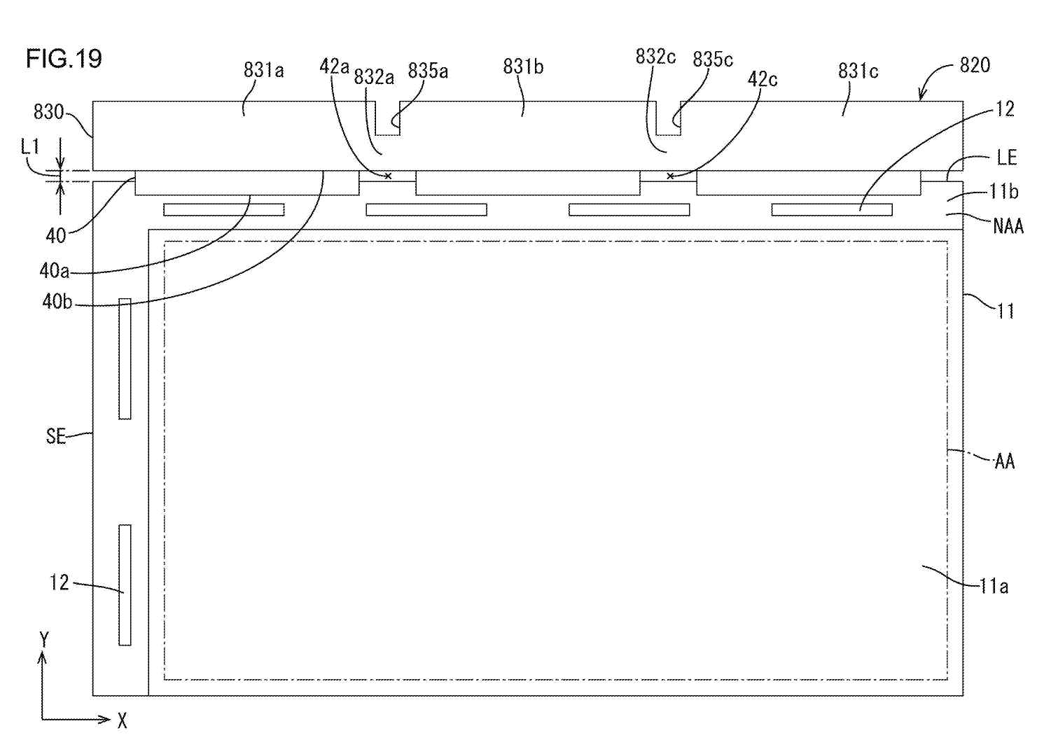

A ninth embodiment of the present invention is described with reference to FIG. 19. In the ninth embodiment, the configuration of a rigid board portion 830 of a rigid flexible board 820 is different from the rigid flexible board 520 in the above-described sixth embodiment. The configurations, operations, and effects similar to those in the above-described sixth embodiment are not described.

In the rigid board portion 830 in this embodiment, a slit 835a (a slit 835c) is a cutout at the second edge 30b of the rigid board 830 remote from the liquid crystal panel 11, unlike the slit 535a (the slit 535c) in the sixth embodiment. This configuration eliminates the need of routing wiring lines so as to avoid the slit 535a (the slit 535c) at the side of the rigid board portion 830 connected to the flexible board portion 40, making it easy to design the rigid board portion 830.

### Tenth Embodiment

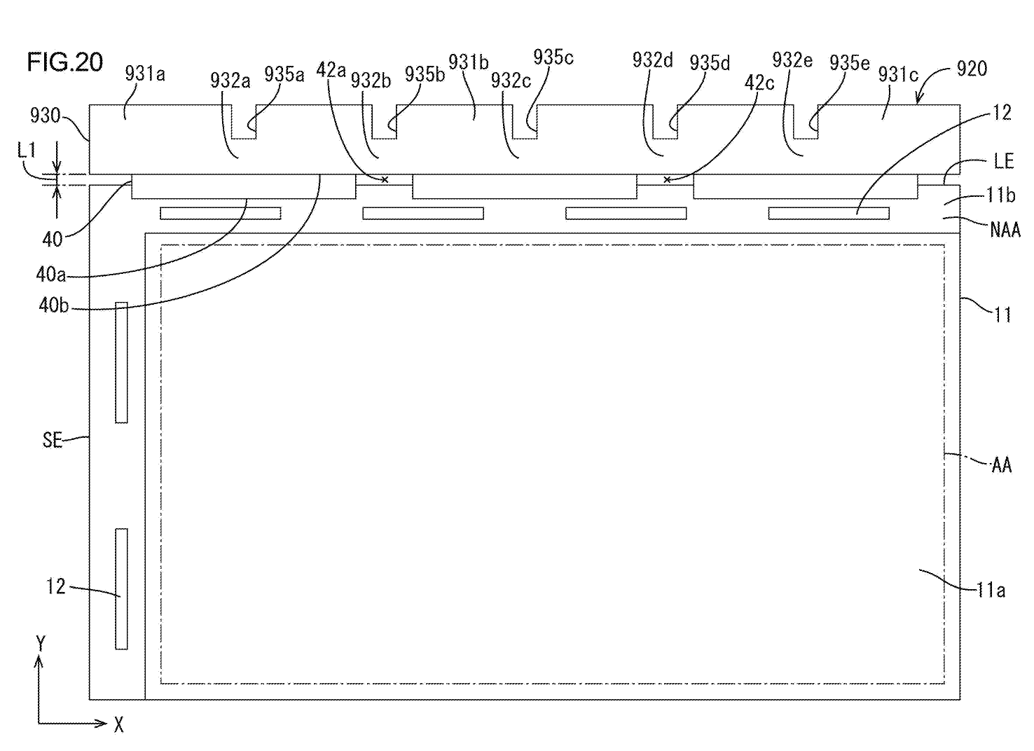

A tenth embodiment of the present invention is described with reference to FIG. 20. In the tenth embodiment, the configuration of a rigid board portion 930 of a rigid flexible board 920 is different from the rigid flexible board 820 in the above-described ninth embodiment. The configurations, operations, and effects similar to those in the above-described ninth embodiment are not described.

The rigid board portion 930 in this embodiment further includes slits at the second edge 30b of the rigid board portion 930 so as to face the connection portions between the rigid board portion 930 and the flexible board portion 40, unlike the ninth embodiment. In other words, at the second edge 30b of the rigid board portion 930, slits 935b and 935d face the spaces 42a and 42c, and slits 935a, 935c, and 935e face the flexible portions 41a, 41b, and 41c. If the first edge 30a of a rigid board portion includes a slit, the slit needs to be positioned away from the connection portion between the rigid board portion 930 and the flexible board portion 40. However, since the slits are positioned at the second edge 30b of the rigid board portion 930 in the present embodiment, the formation positions of the slit 935a to 935e, i.e., the positions of the low rigidity portions 932a to 932e, are determined with a high degree of freedom. The displacement and deformation of the rigid portions 932a to 932f of the rigid board portion 930 is sufficiently absorbed by properly positioning the low rigidity portions 932a to 932e.

### Eleventh Embodiment

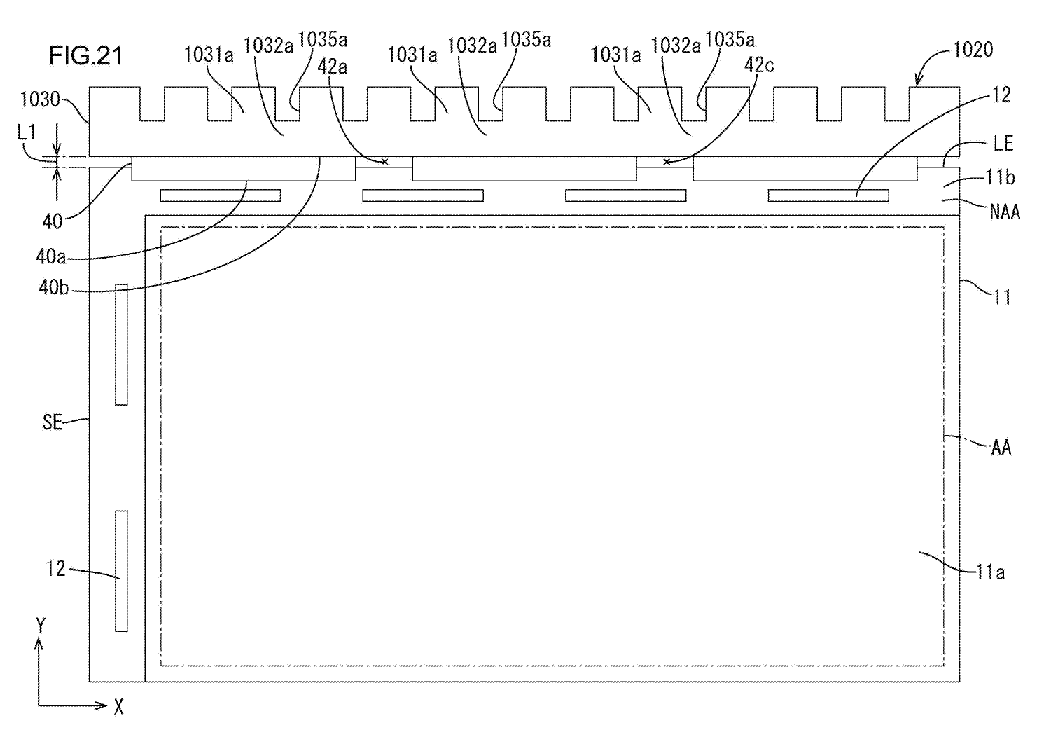

An eleventh embodiment of the present invention is described with reference to FIG. 21. In the eleventh embodiment, the configuration of a rigid board portion 1030 of a rigid flexible board 1020 is different from the rigid flexible board 920 in the above-described eighth embodiment. The configurations, operations, and effects similar to those in the above-described tenth embodiment are not described.

In the rigid board portion 1030 in this embodiment, the second edge 30b of the rigid board portion 1030 includes many slits 1035a, unlike the tenth embodiment. In the rigid board portion 1030, portions constituting rigid portions 1031a and portions constituting low rigidity portions 1032a are repeatedly arranged along the second edge 30b. This configuration reliably enables the rigid board portion 1030 to have high flatness.

### Other Embodiments

The present invention is not limited to the embodiments described above with reference to the drawings. For example, the following embodiments are included in the technical scope of the present invention.

(1) In the above-described embodiments except for the fourth embodiment, the configuration including three or more rigid portions is described as an example, but the number of rigid portions may be at least two. The size of each rigid portion and the number of rigid portions may be suitably changed depending on the material, size, or shape of the signal supply board, or connection configuration of the signal supply board to the flexible board, for example.

(2) In the above-described first embodiment, for example, the configuration in which the flexible board portion is separated such that the number of flexible portions is the same as the number of rigid portions is described as an example, but the configuration of the flexible board portion is not limited to this. For example, the flexible board portion may be unseparated or the number of flexible portions may be larger or smaller than the number of rigid portions.

(3) In the above-described embodiments, the configuration in which the rigid flexible boards in two layers are stacked is described as an example, but a configuration in which rigid members in three or more layers are stacked is included in the present invention.

(4) The configurations of the above-described embodiments may be suitably combined without departing from the spirit of the invention. For example, the slits described in the sixth to eleventh embodiments may be formed in the rigid board described in the seventh embodiment to provide the low rigidity portion.

(5) In the above-described embodiments, the low rigidity portion constituted of a flexible base member or a slit is described as an example, but the configuration of the low rigidity portion is not limited thereto. The low rigidity portion may be formed by thinning a portion of the rigid board portion or a portion of the rigid board.

(6) In the above-described sixth to eleventh embodiments, a configuration in which the slits are cutouts in the rigid board portion is described as an example, but the slit may be a through hole having an opening in a planar surface of the rigid board portion. In such a case, the low rigidity portion is able to be located at each side (for example, a first end and a second end of the rigid board portion) in the longitudinal direction of the slit.

(7) Other than the above-described embodiments, the positions, number, shape, or material of the low rigidity portion may be suitably determined. The rigidity of the low rigidity portion may be suitably changed as long as the rigidity thereof is lower than the rigidity of the rigid portion.

(8) In the above-described embodiments, the liquid crystal panel having a horizontally elongated quadrilateral shape is described as an example, but the present invention is applicable to a liquid crystal panel having a vertically elongated quadrilateral shape or a liquid crystal panel having a square shape. In addition, the present invention is applicable to a liquid crystal panel having another shape such as a semicircular shape and a doughnut shape.

(9) In the above-described embodiments, a transmissive liquid crystal display device including a backlight device, which is an external light source, is described as an example, but the present invention is applicable to a reflective liquid crystal display device configured to provide a display by using external light. In such a case, a backlight device may be eliminated.

(10) In the above-described embodiments, the TFT is used as the switching element in the liquid crystal display device, but the present invention is applicable to a liquid crystal display device that uses a switching element other than a TFT (a thin film diode (TFD), for example). The present invention is also applicable to a black-and-white liquid crystal display device other than a color liquid crystal display device.

(11) In the above-described embodiments, a liquid crystal display device using a liquid crystal panel as a display panel is described as an example, but the present invention is applicable to a display device that uses another type of display panel (such as a PDP (plasma display panel) and an organic EL panel). In such a case, a backlight device may be eliminated.

(12) In the above-described embodiments, the display area located closer to one edge of the liquid crystal panel in the long side direction and one edge in the short side direction is described as an example. However, a display area located at the middle of the liquid crystal panel in the long side direction and closer to one edge in the short side direction and a display area located at the middle of the liquid crystal panel in the short side direction and closer to one edge in the long side direction may be included in the present invention. Meanwhile, a configuration in which the display area is located at the middle of the liquid crystal panel in the long side direction and the short side direction is included in the present invention.

(13) In the above-described embodiments, the rigid flexible board or the rigid board having a length substantially equal to the dimension of the liquid crystal panel in the long side direction is described as an example, but the specific length of the rigid flexible board or the rigid board is suitably changed and may be about half of the dimension of the liquid crystal panel in the long side direction, for example.

### EXPLANATION OF SYMBOLS

11 liquid crystal panel
21 flexible base member
22 rigid base member
30, 130, 230, 330, 530, 730, 830, 930, 1030 rigid board portion
30a first edge
30b second edge
31a, 131a, 231a, 331a, 431a, 531a, 731a, 831a, 931a, 1031a rigid portion
31b, 131b, 231b, 331b, 431b, 531b, 731b, 831b, 931b rigid portion
31c, 131c, 231c, 431c, 531c, 731c, 831c, 931c rigid portion
32a, 132a, 232a, 332a, 432a, 532a, 732a, 832a, 932a, 1032a low rigidity portion
32c, 132c, 232c, 432c, 532c, 732c, 832c, 932c low rigidity portion
37 rigid board side flexible base member (signal supply board side flexible base member)
40 flexible board portion (signal supply board)
40a first end
40b second end
41a flexible portion
41b flexible portion
41c flexible portion
42a space
42c space
430, 630 rigid board (signal supply board)
440 flexible board
LE edge

1. A display device comprising:
a display panel having a display area capable of displaying an image and a non-display area outside the display area;
a flexible board having flexibility and connected to the non-display area at a first end thereof; and
a signal supply board connected to a second end of the flexible board opposite from the first end and configured to supply signals to the display panel through the flexible board, the signal supply board at least including a first rigid portion having a higher rigidity than the flexible board, a second rigid portion located next to the first rigid portion and having a higher rigidity than the flexible board, and a low rigidity portion located between the first rigid portion and the second rigid portion and having a lower rigidity than the first rigid portion and the second rigid portion.

2. The display device according to claim 1, wherein the non-display area extends along an edge of the display panel, and
the first rigid portion and the second rigid portion of the signal supply board are located next to each other along the edge of the display panel.

3. The display device according to claim 2, wherein the flexible board at least includes a first flexible portion and a second flexible portion separately located next to each other along the edge of the display panel with having a space between the first flexible portion and the second flexible portion, and
the first rigid portion and the second rigid portion of the signal supply board are respectively connected to the first flexible portion and the second flexible portion, and the low rigidity portion of the signal supply board faces the space.

4. The display device according to claim 1, wherein the flexible board is connected to the non-display area by thermocompression bonding,
the signal supply board is integrally formed with the flexible board by stacking a rigid base member on a flexible base member constituting the flexible board, the rigid base member having a higher rigidity than the flexible base member, and
the low rigidity portion is constituted of at least a portion of the flexible base member.

5. The display device according to claim 1, wherein the signal supply board is a separate member from the flexible board and is connected to the flexible board by thermocompression bonding, and
the low rigidity portion is a separate member from a flexible base member constituting the flexible board and at least includes a signal supply board side flexible base member having flexibility.

6. The display device according to claim 4, wherein the low rigidity portion extends from a first edge of the signal supply board adjacent to the display panel to a second edge thereof remote from the display panel.

7. The display device according to claim 1, wherein the low rigidity portion includes a slit extending through the signal supply board in a thickness direction thereof.

8. The display device according to claim 7, wherein the slit is a cutout at a first edge of the signal supply board adjacent to the display panel.

9. The display device according to claim 7, wherein the slit is a cutout at a second edge of the signal supply board remote from the display panel.

10. The display device according to claim 7, wherein the slit includes a plurality of slits located close to each other and in parallel to each other.

11. The display device according to claim 1, wherein the display panel is a liquid crystal panel having liquid crystals sealed between two substrates.
